(19) United States
(12) Patent Application Publication
(10) Pub. No.: US 2024/0337996 A1
(43) Pub. Date: Oct. 10, 2024

(54) COMPONENT MOUNTING SYSTEM

(71) Applicant: YAMAHA HATSUDOKI KABUSHIKI KAISHA, Iwata-shi, Shizuoka (JP)

(72) Inventor: Hidekazu SHIMIZU, Shizuoka (JP)

(73) Assignee: YAMAHA HATSUDOKI KABUSHIKI KAISHA, Iwata-shi, Shizuoka (JP)

(21) Appl. No.: 18/579,194

(22) PCT Filed: Aug. 5, 2021
(86) PCT No.: PCT/JP2021/029169

§ 371 Date: Jan. 12, 2024

(51) Int. Cl. G05B 19/04

(52) U.S. Cl. CPC G05B 19/041; G05B 2219/24047

(57) ABSTRACT

A management device of a component mounting system includes a management storage unit, a data generating unit, and a display control unit. The management storage unit stores management data in which production factor information for identifying production factors in a mounting machine and suction error information output from the mounting machine are associated with one another. The data generating unit generates suction error count data and suction error loss amount data in association with the production factor information based on a data group of the management data. The display control unit controls a display unit such that a suction error data set is displayed with the suction error count data and the suction error loss amount data associated with the production factor information selected via an operating unit as one set.

### CROSS-REFERENCE TO RELATED APPLICATION

This application claims benefit of priority to International Patent Application No. PCT/JP2021/029169, filed Aug. 5, 2021, the entire contents of which are incorporated herein by reference.

### BACKGROUND

### Technical Field

The present disclosure relates to a component mounting system equipped with a component mounting line including a mounting machine.

### Background Art

Conventionally, a component mounting system has been known, which is equipped with a component mounting line including a mounting machine that obtains a component loading board by loading electronic components (hereinafter simply referred to as “component”) on a board such as a printed circuit board. In this kind of component mounting system, the mounting machine includes a feeder that supplies the component, and a loading head that includes a suction nozzle that suctions the component supplied by the feeder to load the component on the board.

In the mounting machine, the suction state of the component by the suction nozzle may become an abnormal state and a suction error may occur. If such a component suction error occurs, there is a possibility that loading the component accurately on the board may become impossible. If loading the component accurately on the board is impossible, this will affect the quality of the component loading board produced by the mounting machine. Therefore, if a suction error occurs, actions may be taken to discard the component corresponding to the suction error. In this case, the amount of component that is discarded is the amount of loss in the production of the component loading board.

Japanese Patent Application Laid-Open No. 2008-77644 discloses a technique for managing production of a component loading board in a mounting machine based on the amount of loss of the component caused by the occurrence of a suction error. In the technique disclosed in Japanese Patent Application Laid-Open No. 2008-77644, suction error count data about the occurrence count of the suction error and suction error loss amount data about the amount of loss of the component caused by the occurrence of the suction error are displayed in a display device.

In the technique disclosed in Japanese Patent Application Laid-Open No. 2008-77644, only the suction error count data and the suction error loss amount data are displayed. Therefore, even if display contents on the display device are checked, it is difficult for an operator to identify the generating factor for the suction error in the suction nozzle of the mounting machine. Therefore, it is difficult for the operator to take measures to solve the suction error.

### SUMMARY

Accordingly, the present disclosure provides a component mounting system capable of confirming the generating factor for a suction error in a suction nozzle of the mounting machine by using the amount of loss of the component caused by the suction error as an indicator.

A component mounting system according to one aspect of the present disclosure includes a component mounting line including at least a mounting machine that produces a component loading board with a component loaded; and a management device configured to manage production of the component loading board in the mounting machine. The mounting machine includes a feeder that supplies the component: a loading head including a suction nozzle that suctions the component to obtain the component loading board by loading the component suctioned by the suction nozzle on a board; and a suction state recognition unit configured to recognize a suction state of the component by the suction nozzle and output suction error information when a suction error indicating an abnormality in the suction state occurs. The management device includes a storage unit configured to accumulate and store management data in which production factor information to identify production factors indicated by one of the component, the feeder, the suction nozzle, and the loading head used in the production of the component loading board is associated with the suction error information for each suction of the component by the suction nozzle; and a data generating unit configured to generate error count data about an occurrence count of the suction error and error loss amount data about an amount of loss of the component caused by the occurrence of the suction error in association with each piece of the production factor information based on a data group of the management data accumulated and stored in the storage unit. Also, the management device includes a display unit that enables display of various data: an operating unit to which a command about a display mode of the display unit is input; and a display control unit configured to control the display unit in response to the command input into the operating unit. When a suction error display command to display data about the suction error and a factor selection command to select one of the production factors are input via the operating unit, the display control unit is configured to control the display unit such that an error data set is displayed with the error count data and the error loss amount data associated with the production factor information corresponding to the production factor indicated by the factor selection command as one set.

The object, features, and advantages of the present disclosure will be more apparent from the following detailed description and the accompanying drawings.

### BRIEF DESCRIPTION OF THE DRAWINGS

FIG. 1 is a diagram showing an overall configuration of a component mounting system according to one embodiment of the present disclosure;

FIG. 2 is a block diagram of a mounting machine provided in the component mounting system;

FIG. 3 is a plan view showing a configuration of a mounting machine body in the mounting machine;

FIG. 4 is an enlarged view of a portion of a head unit of the mounting machine body;

FIG. 5 is a block diagram of a management device provided in the component mounting system;

FIG. 6 is a view showing a display screen of a display unit in the management device, showing a state in which a data set group of a suction error data set is displayed;

FIG. 7 is a view showing the display screen of the display unit in the management device, showing a state in which a data set group of a loading error data set is displayed;

FIG. 8 is a view showing the display screen of the display unit in the management device, showing a state in which data set groups corresponding to a plurality of production factors are displayed simultaneously;

FIG. 9 is a view showing an interlocking state of data that constitutes the data set groups displayed in the display unit;

FIG. 10 is a view showing the display screen of the display unit in the management device, showing a display state when a command to set a display narrowing condition is input via an operating unit;

FIG. 11 is a view showing the display screen of the display unit in the management device, showing a state in which an error loss amount transition graph and an error count transition graph are displayed;

FIG. 12 is a view showing the display screen of the display unit in the management device, showing a state in which inspection error loss amount data is displayed;

FIG. 13 is a view showing the display screen of the display unit in the management device, showing a display state when a command to display data for each error type is input via the operating unit; and

FIG. 14 is a view showing the display screen of the display unit in the management device, showing a display state when a command to display data for each of a plurality of mounting lines is input via the operating unit.

### DETAILED DESCRIPTION

A component mounting system according to an embodiment of the present disclosure will be described below with reference to the drawings.

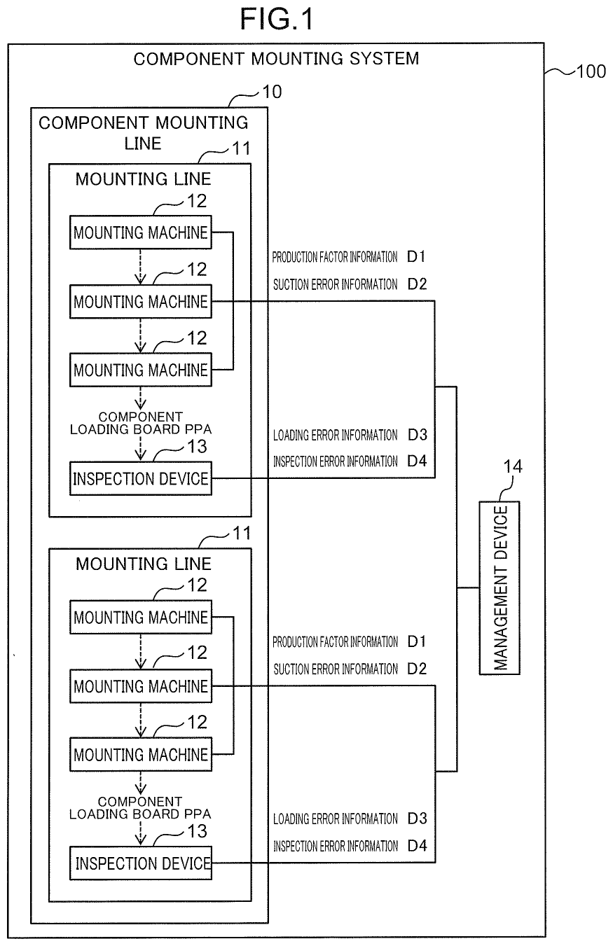

As shown in FIG. 1, a component mounting system 100 according to the present embodiment includes a component mounting line 10 and a management device 14.

The component mounting line 10 includes a plurality of mounting lines 11 including at least mounting machines 12 that each produce a component loading board PPA on which a component is loaded. In each mounting line 11 that constitutes the component mounting line 10, the plurality of mounting machines 12 and an inspection device 13 are connected in a straight line. The management device 14 is a device for managing the production of the component loading board PPA in the mounting machines 12. The management device 14 is connected to the mounting machines 12 and the inspection devices 13 in a way that allows data communication.

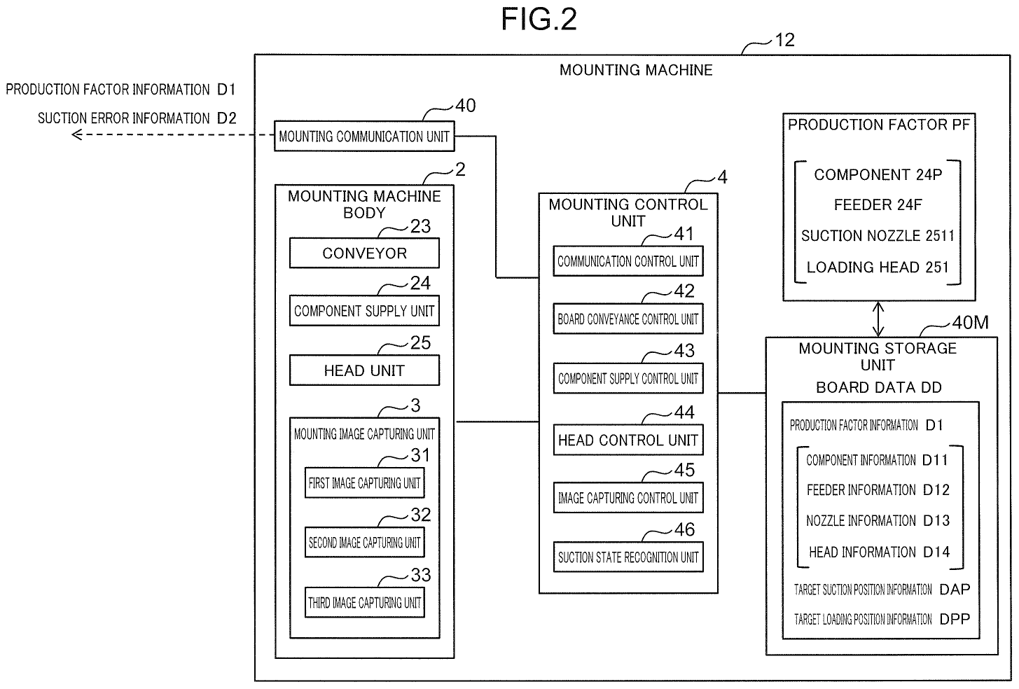

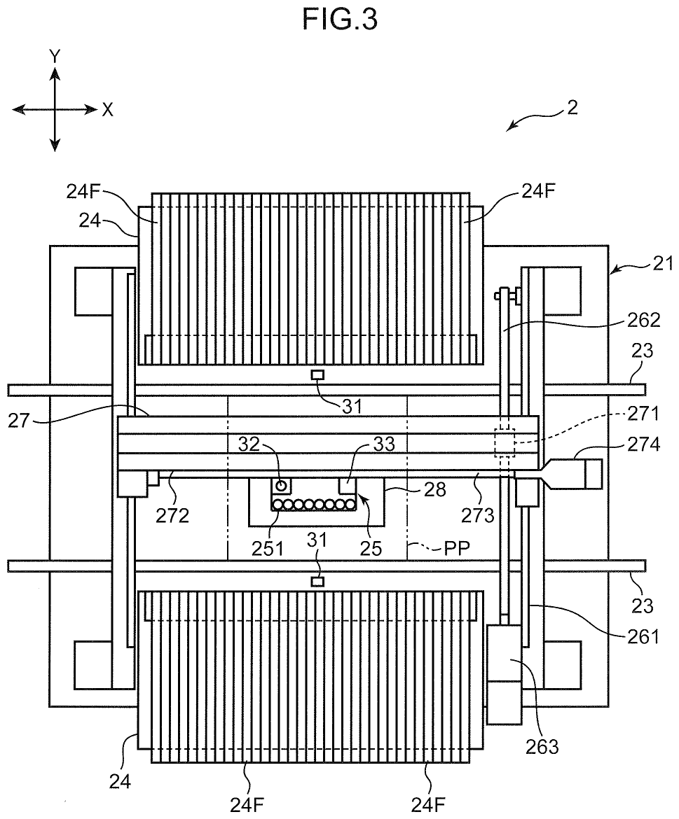

The mounting machine 12 will be described with reference to FIGS. 2 to 4 in addition to FIG. 1. Note that FIG. 3 shows the orientation relationship using XY orthogonal coordinates that are orthogonal to each other on the horizontal plane. The mounting machine 12 is an apparatus for producing the component loading board PPA with electronic components (hereinafter referred to as “component”) loaded on a board PP on which a solder paste pattern is formed.

The mounting machine 12 includes a mounting machine body 2, a mounting control unit 4, a mounting communication unit 40, and a mounting storage unit 40M. The mounting machine body 2 constitutes a structural part that executes a component loading process for loading the component on the board PP, and the like during production of the component loading board PPA. The mounting communication unit 40 is an interface for executing data communication with the management device 14, and has a function of outputting various data and information to the management device 14. The mounting control unit 4 controls the component loading process of the mounting machine body 2 and the like according to board data DD stored in the mounting storage unit 40M and controls the data communication of the mounting communication unit 40.

The mounting machine body 2 includes a body frame 21, a conveyor 23, component supply units 24, a head unit 25, and a board support unit 28.

The body frame 21 is a structure on which respective parts that constitute the mounting machine body 2 are disposed, and is formed in a substantially rectangular shape in plan view when viewed from a direction orthogonal to both the X-axis direction and the Y-axis direction (perpendicular direction). The conveyor 23 extends in the X-axis direction and is disposed on the body frame 21. The conveyor 23 conveys the board PP in the X-axis direction. Positioning of the board PP conveyed on the conveyor 23 is determined by the board support unit 28 at a predetermined work position (component loading position where the component is loaded on the board PP). The board support unit 28 determines positioning of the board PP on the conveyor 23 by supporting the PP from below. Note that FIG. 3 illustrates a single-lane type board conveyance mechanism having one conveyor 23 serving as a lane for conveying the board PP, but this may be a dual-lane type board conveyance mechanism having two conveyors 23.

The component supply units 24 are disposed in regions at both ends of the body frame 21 in the Y-axis direction, with the conveyor 23 interposed therebetween. Each of the component supply units 24 is a region installed in the body frame 21 with a plurality of feeders 24F installed in parallel, and the set position of each feeder 24F is divided for each component 24P to be held by loading heads 251 provided in the head unit 25 to be described later. Each of the feeders 24F is detachably installed in the component supply unit 24. The feeder 24F is a device that executes a component supply process to supply the component. The feeder 24F is not particularly limited as long as the feeder can hold a plurality of components 24P and supply the held components 24P to predetermined component supply positions set in the feeder, and is, for example, a tape feeder. The tape feeder is a feeder including a reel on which a component storage tape that stores the component 24P at predetermined intervals is wound, and configured to supply the component 24P by feeding the component storage tape from the reel.

The head unit 25 is held by a moving frame 27. A fixed rail 261 extending in the Y-axis direction and a ball screw shaft 262 rotationally driven by a Y-axis servomotor 263 are disposed on the body frame 21. The moving frame 27 is disposed on the fixed rail 261, and a nut portion 271 provided in the moving frame 27 is screwed into the ball screw shaft 262. A guide member 272 extending in the X-axis direction and a ball screw shaft 273 driven by an X-axis servomotor 274 are disposed on the moving frame 27. The head unit 25 is movably held by the guide member 272, and the nut portion provided in the head unit 25 is screwed into the ball screw shaft 273. The moving frame 27 is moved by the operation of the Y-axis servomotor 263 in the Y-axis direction, and the head unit 25 is moved by the operation of the X-axis servomotor 274 in the X-axis direction with respect to the moving frame 27. That is, the head unit 25 is movable in the Y-axis direction as the moving frame 27 moves, and is movable in the X-axis direction along the moving frame 27. The head unit 25 is movable between the component supply unit 24 and the board PP supported by the board support unit 28. The head unit 25 executes the component loading process for loading the component 24P onto the board PP by moving between the component supply unit 24 and the board PP.

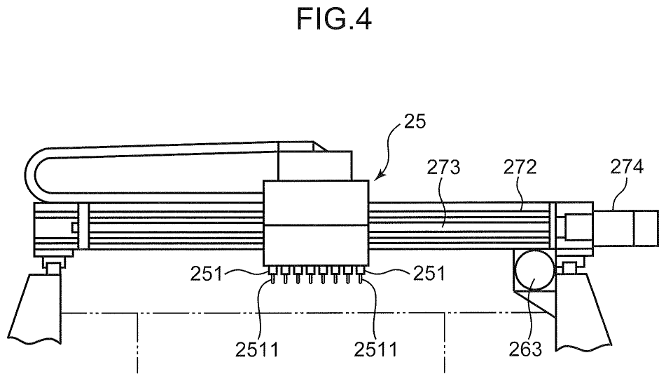

As shown in FIG. 4, the head unit 25 includes the plurality of loading heads 251. Each loading head 251 includes a suction nozzle 2511 installed on the tip (lower end). The suction nozzle 2511 is a nozzle capable of suctioning and holding the component 24P supplied by the feeder 24F. The suction nozzle 2511 executes a component suction process for suctioning the component 24P. The suction nozzle 2511 can communicate with any one of a negative pressure generation device, a positive pressure generation device, and the atmosphere via an electric switching valve. That is, the supply of negative pressure to the suction nozzle 2511 enables the suctioning and holding of the component 24P by the suction nozzle 2511. After that, the supply of positive pressure releases the suctioning and holding of the component 24P. Each loading head 251 executes the component loading process for loading the component 24P suctioned and held by the suction nozzle 2511 onto the board PP at each of a plurality of target loading positions set on the board PP. Each loading head 251 executes the component loading process on the PP to obtains the component loading board PPA.

Each loading head 251 can ascend and descend in the Z-axis direction (perpendicular direction) with respect to the frame of the head unit 25, and can rotate around the head axis extending in the Z-axis direction. Each loading head 251 can ascend and descend along the Z-axis direction between a suctionable position where the suction nozzle 2511 can suction and hold the component 24P and a retracted position above the suctionable position. That is, when the suction nozzle 2511 suctions and holds the component 24P, each loading head 251 descends from the retracted position toward the suctionable position, and suctions and holds the component 24P at the suctionable position. Meanwhile, each loading head 251 after suctioning and holding the component 24P ascends from the suctionable position toward the retracted position. Furthermore, each loading head 251 can ascend and descend along the Z-axis direction between a loadable position where the component 24P suctioned and held by the suction nozzle 2511 can be loaded at the predetermined target loading position on the board PP, and the retracted position.

As shown in FIGS. 2 and 3, the mounting machine body 2 further includes a mounting image capturing unit 3. The mounting image capturing unit 3 acquires a captured image by executing an image capturing operation of capturing an image of an object to be captured. The mounting image capturing unit 3 includes a first image capturing unit 31, a second image capturing unit 32, and a third image capturing unit 33.

The first image capturing unit 31 is, for example, an image capturing camera installed between the component supply unit 24 and the conveyor 23 on the body frame 21 and including an image capturing element such as a complementary metal-oxide-semiconductor (CMOS) and a charged-coupled device (CCD). When each loading head 251 is executing the component loading process, while the head unit 25 is moving from the component supply unit 24 to the board PP supported by the board support unit 28, the first image capturing unit 31 captures an image of the component 24P suctioned and held by the suction nozzle 2511 of each loading head 251 from below to acquire a suction processing image. The suction processing image is an image indicating a processing state of the component suction process by the suction nozzle 2511. The suction processing image is, for example, an image that allows checking the posture of the component 24P suctioned to the suction nozzle 2511, an offset amount of the suction position of the component 24P from the suction nozzle 2511, and the like as the processing state of the component suction process. The suction processing image is input into the mounting control unit 4 described later, and is referred to when a suction state recognition unit 46 executes a recognition process of the suction state of the component 24P with respect to the suction nozzle 2511.

The second image capturing unit 32 is, for example, an image capturing camera disposed in the head unit 25 and including a CMOS or CCD image capturing element or the like. The second image capturing unit 32 captures an image of the component supply position of the feeder 24F from diagonally above, with the head unit 25 disposed such that the suction nozzle 2511 is positioned directly above the component supply position set in the feeder 24F. Specifically, before the suction nozzle 2511 executes the suction operation, the second image capturing unit 32 acquires a first supply processing image by capturing an image of the component 24P supplied to the component supply position by the feeder 24F from diagonally above. Furthermore, the second image capturing unit 32 captures the state of the component supply position while the suction nozzle 2511 is executing the suction operation on the component 24P supplied to the component supply position by the feeder 24F to acquire a second supply processing image. The second image capturing unit 32 captures the state of the component supply position after the suction nozzle 2511 finishes the suction operation to acquire a third supply processing image. The first supply processing image is an image that allows checking of the posture of the component 24P supplied to the component supply position of the feeder 24F. The second supply processing image and the third supply processing image are images that allow checking of the posture of the component 24P supplied to the component supply position when suctioned by the suction nozzle 2511. The first to third supply processing images are input into the mounting control unit 4, and are referred to when the suction state recognition unit 46 executes the recognition process of the suction state of the component 24P with respect to the suction nozzle 2511.

The second image capturing unit 32 captures an image of the target loading position from diagonally above with the head unit 25 disposed such that the suction nozzle 2511 that suctions and holds the component is positioned directly above the target loading position set on the board PP. Specifically, before the loading head 251 loads the component 24P suctioned by the suction nozzle 2511 onto the board PP, the second image capturing unit 32 captures an image of the target loading position on the board PP from diagonally above to acquire a first loading processing image. Furthermore, the second image capturing unit 32 captures an image of the state of the target loading position after the loading head 251 finishes the component loading operation to acquire a second loading processing image. The first loading processing image and the second loading processing image are images indicating the processing state of the component loading process by the loading head 251. The first loading processing image and the second loading processing image are, for example, images that enable checking of the posture of the component 24P loaded at the target loading position on the board PP and the like as the processing state of the component loading process.

The third image capturing unit 33 is, for example, an image capturing camera disposed in the head unit 25 and including a CMOS or CCD image capturing element or the like. To recognize various marks affixed to an upper surface of the board PP supported by the board support unit 28 when each loading head 251 is executing the component loading process, the third image capturing unit 33 captures an image of the marks from above. By recognizing the marks on the board PP by the third image capturing unit 33, the position offset amount with respect to origin coordinates of the board PP is detected.

The mounting storage unit 40M stores the board data DD to be referred to by the mounting control unit 4. The board data DD is data including a plurality of pieces of production factor information D1 required to control the component loading process of the mounting machine body 2 and the like by the mounting control unit 4, target suction position information DAP, and target loading position information DPP.

The production factor information D1 is information for identifying production factors PF indicated by either of the component 24P, the feeder 24F, the suction nozzle 2511, and the loading head 251 used for production of the component loading board PPA in the mounting machine 12. In the present embodiment, the production factor information D1 includes component information D11, feeder information D12, nozzle information D13, and head information D14.

The component information D11 is information for identifying the component 24P out of the production factors PF. In the component information D11, as information for identifying the component 24P, information such as the component name unique to the component 24P, the component type indicating the type of the component 24P, and external dimensions of the component 24P is registered. The feeder information D12 is information for identifying the feeder 24F out of the production factors PF. In the feeder information D12, as information for identifying the feeder 24F, information such as the type of the feeder 24F and the set position of the feeder 24F in the component supply unit 24 is registered. The nozzle information D13 is information for identifying the suction nozzle 2511 out of the production factors PF. In the nozzle information D13, as information for identifying the suction nozzle 2511, information such as the type of the suction nozzle 2511 and an identifier of the suction nozzle 2511 is registered. The head information D14 is information for identifying the loading head 251 out of the production factors PF. In the head information D14, as information for identifying the loading head 251, information such as the serial number of the loading head 251 is registered.

The target suction position information DAP is information in which the target suction position when the suction nozzle 2511 suctions the component 24P (target suction position) is registered. In the target suction position information DAP, coordinates of the target suction position of the component 24P with respect to the suction nozzle 2511 in the X-axis and Y-axis directions are registered. The target suction position is usually set at the central position on the surface to be suctioned in the component 24P. The target loading position information DPP is information in which the target loading position of the component 24P set on the board PP is registered. In the target loading position information DPP, coordinates of the target loading position on the board PP in the X-axis and Y-axis directions are registered.

The mounting control unit 4 includes a central processing unit (CPU), a read only memory (ROM) that stores a control program, a random access memory (RAM) used as a work area for the CPU, and the like. By the CPU executing the control program stored in the ROM, the mounting control unit 4 controls the operation of each constituent element of the mounting machine body 2, controls the data communication operation of the mounting communication unit 40, and further executes various kinds of arithmetic processing. The mounting control unit 4 controls the operation of each constituent element of the mounting machine body 2 according to the board data DD stored in the mounting storage unit 40M. As shown in FIG. 2, the mounting control unit 4 includes, as main functional configurations, a communication control unit 41, a board conveyance control unit 42, a component supply control unit 43, a head control unit 44, an image capturing control unit 45, and the suction state recognition unit 46.

The communication control unit 41 controls data communication between the mounting machine 12 and the management device 14 by controlling the mounting communication unit 40. The mounting communication unit 40 controlled by the communication control unit 41 sends, to the management device 14, suction error information D2 output by the suction state recognition unit 46 described later and the production factor information D1 included in the board data DD stored in the mounting storage unit 40M. Note that the production factor information D1 sent to the management device 14 via the mounting communication unit 40 includes the component information D11, the feeder information D12, the nozzle information D13, and the head information D14.

Although details will be described later, the suction error information D2 is data output from the suction state recognition unit 46 when a suction error indicating an abnormality in the suction state of the component 24P occurs in the component suction process by the suction nozzle 2511. In one execution of the component suction process by the suction nozzle 2511, one component 24P is used from among the plurality of components 24P, one feeder 24F is used from among the plurality of feeders 24F, one suction nozzle 2511 is used from among the plurality of suction nozzles 2511, and one loading head 251 is used from among the plurality of loading heads 251. That is, for each component suction process by the suction nozzle 2511, the component 24P, the feeder 24F, the suction nozzle 2511, and the loading head 251 that constitute the production factors PF used for production of the component loading board PPA are uniquely determined. Therefore, the production factor information D1 for identifying the production factors PF and the suction error information D2 output from the suction state recognition unit 46 are information associated with each other for each component suction process by the suction nozzle 2511.

The board conveyance control unit 42 controls the conveyance operation of the board PP by the conveyor 23. The component supply control unit 43 controls the component supply process of each of the plurality of feeders 24F arranged in the component supply unit 24 according to the component information D11 and the feeder information D12 in the board data DD. The head control unit 44 controls the suction nozzle 2511 and the loading head 251 by controlling the head unit 25 according to the component information D11, the nozzle information D13, the head information D14, the target suction position information DAP, and the target loading position information DPP in the board data DD. Accordingly, the head control unit 44 executes the component suction process by the suction nozzle 2511 and executes the component loading process by the loading head 251 corresponding to each of the plurality of target loading positions set on the board PP. The image capturing control unit 45 controls the image capturing operation by the first image capturing unit 31, the second image capturing unit 32, and the third image capturing unit 33 that constitute the mounting image capturing unit 3.

The suction state recognition unit 46 recognizes the suction state of the component 24P by the suction nozzle 2511 based on the suction processing image acquired by the first image capturing unit 31 and the first to third supply processing images acquired by the second image capturing unit 32. Then, when the suction error indicating an abnormality of the suction state of the component 24P by the suction nozzle 2511 occurs, the suction state recognition unit 46 outputs the suction error information D2.

Specifically, the suction state recognition unit 46 recognizes whether the component 24P is suctioned to the suction nozzle 2511 based on the suction processing image. When the component 24P is not suctioned to the suction nozzle 2511, the suction state recognition unit 46 recognizes that the suction error of component fall indicating the fall of the component 24P from the suction nozzle 2511 has occurred, and outputs the suction error information D2 to which information on the component fall error is added. Meanwhile, when the component 24P is suctioned to the suction nozzle 2511, the suction state recognition unit 46 recognizes the actual suction position indicating the actual suction position of the component 24P by the suction nozzle 2511 based on the suction processing image. When the actual suction position deviates beyond the allowable range from the target suction position indicated by the target suction position information DAP, the suction state recognition unit 46 recognizes that a suction error of suction position offset has occurred, and outputs the suction error information D2 to which information on the suction position offset error is added.

The suction state recognition unit 46 recognizes the posture of the component 24P that is suctioned and held by the suction nozzle 2511 based on the first to third supply processing images. When the component 24P suctioned and held by the suction nozzle 2511 is in an abnormal posture, the suction state recognition unit 46 recognizes that a suction error of component posture has occurred, and outputs the suction error information D2 to which information on the component posture error is added.

As described above, when a suction error occurs in the component suction process by the suction nozzle 2511, the suction state recognition unit 46 outputs the suction error information D2 to which information on the suction error type indicating the type of suction error such as component fall error, suction position offset error, and component posture error is added. The suction error information D2 output from the suction state recognition unit 46 is sent to the management device 14 via the mounting communication unit 40 in association with the component information D11, the feeder information D12, the nozzle information D13, and the head information D14 that constitute the production factor information D1.

Returning to FIG. 1, the component loading board PPA produced by the mounting machine 12 is brought into the inspection device 13. The inspection device 13 is a device for inspecting the loading state of the component 24P on the component loading board PPA. The inspection device 13 may inspect the component loading board PPA before the reflow process of melting and then hardening solder on the component loading board PPA, and may inspect the component loading board PPA after the reflow process.

The inspection device 13 outputs loading error information D3 when a loading error indicating an abnormality in the loading state of the component 24P on the component loading board PPA occurs.

Specifically, the inspection device 13 inspects the posture of the component 24P on the component loading board PPA, the offset amount of the loading position of the component 24P, and the like. When the posture of the component 24P on the component loading board PPA is abnormal, the inspection device 13 recognizes that a loading error of component posture has occurred and outputs the loading error information D3 to which information on the component posture error is added. When the offset amount of the loading position of the component 24P from the target loading position indicated by the target loading position information DPP exceeds the allowable range, the inspection device 13 recognizes that a loading error of loading position offset has occurred, and outputs the loading error information D3 to which information on the loading position offset error is added.

The inspection device 13 inspects coplanarity of the component loading board PPA, and a lead pitch, lead width, the number of leads, and the like of leads of the component 24P on the component loading board PPA. Coplanarity of the component loading board PPA refers to flatness of the component loading board PPA by using the maximum gap between contact points such as the lead and solder ball of the component 24P and the board surface as an indicator. When the maximum gap exceeds the allowable range, the inspection device 13 recognizes that a loading error of coplanarity in the component loading board PPA has occurred and outputs the loading error information D3 to which information on the coplanarity error is added. When the lead pitch of the component 24P on the component loading board PPA exceeds the allowable range, the inspection device 13 recognizes that a loading error of the lead pitch of the component 24P has occurred, and outputs the loading error information D3 to which information on the lead pitch error is added. When the lead width of the component 24P on the component loading board PPA exceeds the allowable range, the inspection device 13 recognizes that a loading error of the lead width of the component 24P has occurred, and outputs the loading error information D3 to which information on the lead width error is added. When the number of leads of the component 24P on the component loading board PPA indicates an abnormal value, the inspection device 13 recognizes that a loading error of the number of leads of the component 24P has occurred, and outputs the loading error information D3 to which information on the number of leads error is added.

As described above, when the loading error indicating an abnormality in the loading state of the component 24P on the component loading board PPA has occurred, the inspection device 13 outputs the loading error information D3 to which loading error type information indicating the type of loading error is added, such as a component posture error, loading position offset error, coplanarity error, lead pitch error, lead width error, and the number of leads error. The loading error information D3 output from the inspection device 13 is sent to the management device 14.

When the loading error information D3 is output from the inspection device 13, if it is possible to replace the component 24P of the loading error with a new component, the operator discards the component 24P of the loading error and executes work to repair the component loading board PPA by replacement with a new component. Meanwhile, if it is impossible to replace the component 24P of the loading error with a new component, the operator discards the component loading board PPA. In this case, all the components 24P on the component loading board PPA are discarded. In this way, when there is a waste component indicating a component to be discarded together with the component loading board PPA due to an inspection error in the inspection device 13, the operator inputs inspection error information D4 for identifying the waste component into the inspection device 13. When the inspection error information D4 is input into the inspection device 13 by the operation of the operator, the inspection device 13 sends the inspection error information D4 to the management device 14.

The management device 14 is a device for managing the production of the component loading board PPA in the mounting machines 12. The management device 14 is connected to the mounting machine 12 and the inspection device 13 in a way that allows data communication, and includes, for example, a microcomputer. The production factor information D1 and the suction error information D2 from the mounting machine 12 are input into the management device 14, and the loading error information D3 and the inspection error information D4 from the inspection device 13 are input. The management device 14 is operated by the operator.

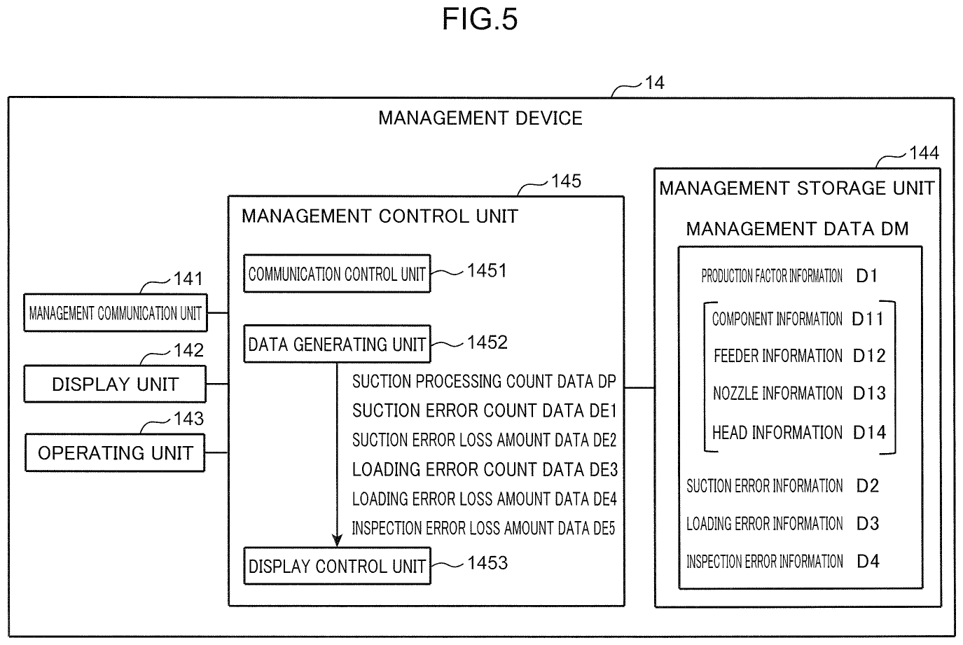

A configuration of the management device 14 will be described with reference to the block diagram of FIG. 5. The management device 14 includes a management communication unit 141, a display unit 142, an operating unit 143, a management storage unit 144, and a management control unit 145.

The management communication unit 141 is an interface for executing data communication with the mounting machine 12 and the inspection device 13. The management communication unit 141 acquires the production factor information D1 and the suction error information D2 from the mounting machine 12, and acquires the loading error information D3 and the inspection error information D4 from the inspection device 13.

The management storage unit 144 accumulates and stores various pieces of information acquired by the management communication unit 141. The management storage unit 144 accumulates and stores management data DM in which the production factor information D1 for identifying the production factor PF used for the production of the component loading board PPA in the mounting machine 12, the suction error information D2, and the loading error information D3 associated with one another for each component suction process by the suction nozzle 2511. The management storage unit 144 is configured, when the management communication unit 141 acquires the inspection error information D4 sent from the inspection device 13, to accumulate and store the management data DM to which the inspection error information D4 is added.

The display unit 142 is configured to display various data. The display unit 142 includes, for example, a liquid crystal display or the like. The operating unit 143 includes a keyboard, a mouse, a touch panel provided in the display unit 142, or the like. The operating unit 143 receives various command input operations by the operator about a display mode of the display unit 142.

The management control unit 145 includes, as main functional configurations, a communication control unit 1451, a data generating unit 1452, and a display control unit 1453.

The communication control unit 1451 controls data communication between the management device 14 and the mounting machine 12, and controls data communication between the management device 14 and the inspection device 13 by controlling the management communication unit 141.

The data generating unit 1452 generates suction processing count data DP, suction error count data DE1, and suction error loss amount data DE2 in association with the component information D11, the feeder information D12, the nozzle information D13, and the head information D14 that constitute the production factor information D1 based on a data group of the management data DM accumulated and stored in the management storage unit 144.

The suction processing count data DP is data corresponding to the number of times the suction nozzle 2511 executes the component suction process in production of the component loading board PPA by the mounting machine 12 within a predetermined period. The predetermined period can be designated by an input operation on the operating unit 143. For example, the suction processing count data DP associated with the component information D11 is data indicating the number of times the suction nozzle 2511 executes the component suction process on the component 24P identified by the component information D11 within the predetermined period. Similarly, the suction processing count data DP associated with the feeder information D12 is data indicating the number of times the suction nozzle 2511 executes the component suction process on the component 24P supplied by the feeder 24F identified by the feeder information D12 within the predetermined period. The suction processing count data DP associated with the nozzle information D13 is data indicating the number of times the suction nozzle 2511 identified by the nozzle information D13 executes the component suction process within the predetermined period. The suction processing count data DP associated with the head information D14 is data indicating the number of times the suction nozzle 2511 attached to the loading head 251 identified by the head information D14 executes the component suction process within the predetermined period.

The data generating unit 1452 generates the suction processing count data DP corresponding to each piece of the production factor information D1 based on the number of pieces of production factor information D1 included in the data group of the management data DM accumulated and stored in the management storage unit 144 in the predetermined period.

The suction error count data DE1 is data corresponding to an occurrence count of suction errors in production of the component loading board PPA by the mounting machine 12 within the predetermined period. For example, the suction error count data DE1 associated with the component information D11 is data indicating the occurrence count of suction errors that occur in correspondence with the component 24P identified by the component information D11 within the predetermined period. Similarly, the suction error count data DE1 associated with the feeder information D12 is data indicating the occurrence count of suction errors that occur in correspondence with the feeder 24F identified by the feeder information D12 within the predetermined period. The suction error count data DE1 associated with the nozzle information D13 is data indicating the occurrence count of suction errors that occur in correspondence with the suction nozzle 2511 identified by the nozzle information D13 within the predetermined period. The suction error count data DE1 associated with the head information D14 is data indicating the occurrence count of suction errors that occur in correspondence with the loading head 251 identified by the head information D14 within the predetermined period.

The data generating unit 1452 generates the suction error count data DE1 corresponding to each piece of the production factor information D1 based on the number of pieces of suction error information D2 included in the data group of the management data DM accumulated and stored in the management storage unit 144 in the predetermined period.

The suction error loss amount data DE2 is data corresponding to the amount of loss of the component 24P caused by the occurrence of the suction error in production of the component loading board PPA by the mounting machine 12 within the predetermined period. For example, the suction error loss amount data DE2 associated with the component information D11 is data indicating the amount of loss of the component 24P caused by the occurrence of the suction error corresponding to the component 24P identified by the component information D11 within the predetermined period. Similarly, the suction error loss amount data DE2 associated with the feeder information D12 is data indicating the amount of loss of the component 24P caused by the occurrence of the suction error corresponding to the feeder 24F identified by the feeder information D12 within the predetermined period. The suction error loss amount data DE2 associated with the nozzle information D13 is data indicating the amount of loss of the component 24P caused by the occurrence of the suction error corresponding to the suction nozzle 2511 identified by the nozzle information D13 within the predetermined period. The suction error loss amount data DE2 associated with the head information D14 is data indicating the amount of loss of the component 24P caused by the occurrence of the suction error corresponding to the loading head 251 identified by the head information D14 within the predetermined period.

The data generating unit 1452 generates the suction error loss amount data DE2 corresponding to each piece of the production factor information D1 based on the number of pieces of the suction error information D2 included in the data group of the management data DM accumulated and stored in the management storage unit 144 in the predetermined period and a unit price of the component 24P. Note that the suction error loss amount data DE2 includes data indicating the amount of loss of the component 24P per one suction error, and data indicating the total amount of loss of the component 24P corresponding to all the suction errors within the predetermined period in the production factor PF identified by the production factor information D1 associated with the suction error loss amount data DE2.

In the present embodiment, the data generating unit 1452 generates loading error count data DE3 and loading error loss amount data DE4 in association with each of the component information D11, the feeder information D12, the nozzle information D13, and the head information D14 that constitute the production factor information D1 based on the data group of the management data DM accumulated and stored in the management storage unit 144.

The loading error count data DE3 is data corresponding to the occurrence count of loading errors in the production of the component loading board PPA by the mounting machine 12 within the predetermined period. For example, the loading error count data DE3 associated with the component information D11 is data indicating the occurrence count of loading errors that occur in correspondence with the component 24P identified by the component information D11 within the predetermined period. Similarly, the loading error count data DE3 associated with the feeder information D12 is data indicating the occurrence count of loading errors that occur in correspondence with the feeder 24F identified by the feeder information D12 within the predetermined period. The loading error count data DE3 associated with the nozzle information D13 is data indicating the occurrence count of loading errors that occur in correspondence with the suction nozzle 2511 identified by the nozzle information D13 within the predetermined period. The loading error count data DE3 associated with the head information D14 is data indicating the occurrence count of loading errors that occur in correspondence with the loading head 251 identified by the head information D14 within the predetermined period.

The data generating unit 1452 generates the loading error count data DE3 corresponding to each piece of the production factor information D1 based on the number of pieces of loading error information D3 included in the data group of the management data DM accumulated and stored in the management storage unit 144 in the predetermined period.

The loading error loss amount data DE4 is data corresponding to the amount of loss of the component 24P caused by the occurrence of the loading error in production of the component loading board PPA by the mounting machine 12 within the predetermined period. For example, the loading error loss amount data DE4 associated with the component information D11 is data indicating the amount of loss of the component 24P caused by the occurrence of the loading error corresponding to the component 24P identified by the component information D11 within the predetermined period. Similarly, the loading error loss amount data DE4 associated with the feeder information D12 is data indicating the amount of loss of the component 24P caused by the occurrence of the loading error corresponding to the feeder 24F identified by the feeder information D12 within the predetermined period. The loading error loss amount data DE4 associated with the nozzle information D13 is data indicating the amount of loss of the component 24P caused by the occurrence of the loading error corresponding to the suction nozzle 2511 identified by the nozzle information D13 within the predetermined period. The loading error loss amount data DE4 associated with the head information D14 is data indicating the amount of loss of the component 24P caused by the occurrence of the loading error corresponding to the loading head 251 identified by the head information D14 within the predetermined period.

The data generating unit 1452 generates the loading error loss amount data DE4 corresponding to each piece of the production factor information D1 based on the number of pieces of loading error information D3 included in the data group of the management data DM accumulated and stored in the management storage unit 144 in the predetermined period and the unit price of the component 24P. Note that the loading error loss amount data DE4 includes data indicating the amount of loss of the component 24P per one loading error, and data indicating the total amount of loss of the component 24P corresponding to all the loading errors within the predetermined period in the production factor PF identified by the production factor information D1 associated with the loading error loss amount data DE4.

In the present embodiment, when the inspection error information D4 is added to the management data DM accumulated and stored in the management storage unit 144, the data generating unit 1452 generates inspection error loss amount data DE5 in association with the inspection error information D4. The inspection error loss amount data DE5 is data corresponding to the amount of loss of the waste component indicating the component 24P discarded together with the component loading board PPA due to the inspection error in the inspection device 13 in the production of the component loading board PPA by the mounting machine 12 within the predetermined period. The data generating unit 1452 generates the inspection error loss amount data DE5 corresponding to the inspection error information D4 based on the number of pieces of inspection error information D4 included in the data group of the management data DM accumulated and stored in the management storage unit 144 in the predetermined period, and the unit price of the component 24P corresponding to the waste component identified by the inspection error information D4.

The display control unit 1453 controls the display unit 142 in response to a command input into the operating unit 143.

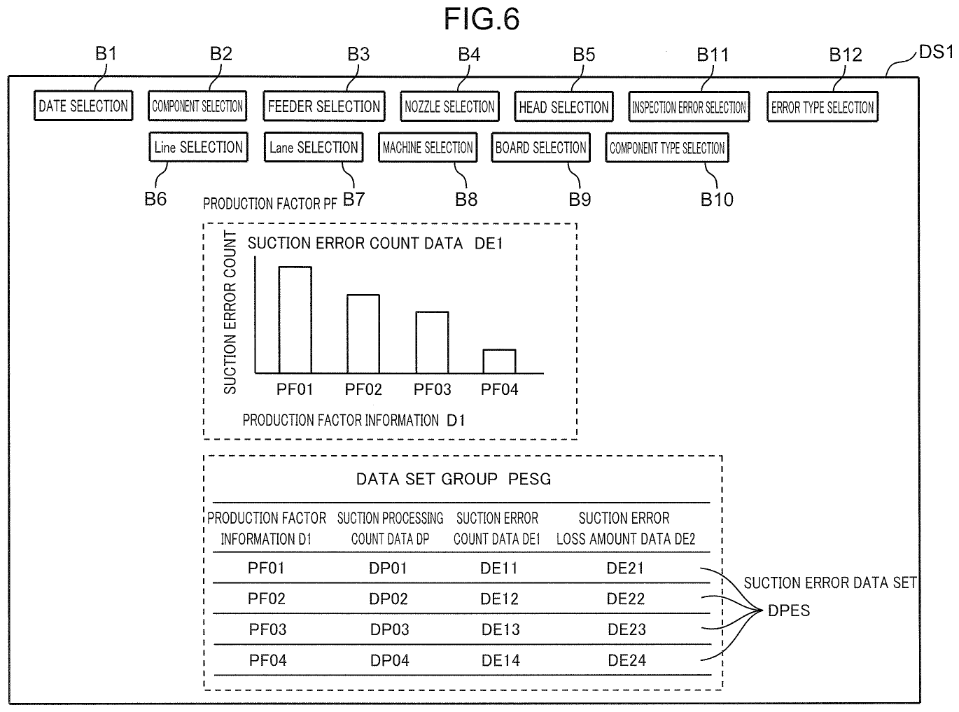

When a suction error display command to display data about the suction error and a factor selection command to select any one of the component 24P, the feeder 24F, the suction nozzle 2511, and the loading head 251 that constitute the production factors PF are input via the operating unit 143, the display control unit 1453 causes the display unit 142 to display a display screen DS1 as shown in FIG. 6. Specifically, the display control unit 1453 controls the display unit 142 such that a suction error data set DPES with the suction error count data DE1 and the suction error loss amount data DE2 associated with the production factor information D1 corresponding to the production factor PF indicated by the factor selection command as one pair is displayed in the display screen DS1. At this time, the display control unit 1453 causes the display screen DS1 to display the suction error data set DPES in which the production factor information D1, the suction processing count data DP, the suction error count data DE1, and the suction error loss amount data DE2 are associated with one another.

For example, when the factor selection command is a command to select the component 24P, the display control unit 1453 causes the display screen DS1 to display the suction error data set DPES with the suction error count data DE1 and the suction error loss amount data DE2 associated with the component information D11 to identify the component 24P as one set. Similarly, when the factor selection command is a command to select the feeder 24F, the display control unit 1453 causes the display screen DS1 to display the suction error data set DPES with the suction error count data DE1 and the suction error loss amount data DE2 associated with the feeder information D12 to identify the feeder 24F as one set. When the factor selection command is a command to select the suction nozzle 2511, the display control unit 1453 causes the display screen DS1 to display the suction error data set DPES with the suction error count data DE1 and the suction error loss amount data DE2 associated with the nozzle information D13 to identify the suction nozzle 2511 as one set. When the factor selection command is a command to select the loading head 251, the display control unit 1453 causes the display screen DS1 to display the suction error data set DPES with the suction error count data DE1 and the suction error loss amount data DE2 associated with the head information D14 to identify the loading head 251 as one set.

At this time, as shown in FIG. 6, the display control unit 1453 may control the display unit 142 such that the suction error count data DE1 or the suction error loss amount data DE2, and the suction error data set DPES are displayed simultaneously in the display screen DS1.

The display control unit 1453 controls the management display unit 162 such that a date selection region B1, a component selection region B2, a feeder selection region B3, a nozzle selection region B4, and a head selection region B5 that allow input operations via the operating unit 143 are set in the display screen DS1.

By using the operating unit 143 to operate the date selection region B1, the operator can select the predetermined period that is a period in which the data generating unit 1452 generates the suction processing count data DP, the suction error count data DE1, and the suction error loss amount data DE2 that constitute the suction error data set DPES. For example, when the predetermined period is selected by an input operation into the date selection region B1, the display control unit 1453 causes the display screen DS1 to display the suction error data set DPES corresponding to the predetermined period.

The component selection region B2, the feeder selection region B3, the nozzle selection region B4, and the head selection region B5 set in the display screen DS1 are regions for inputting the factor selection command to select any one of the component 24P, the feeder 24F, the suction nozzle 2511, and the loading head 251 that constitute the production factors PF. By using the operating unit 143 to operate the component selection region B2, the operator can input the command to select the component 24P from among the production factors PF. Similarly, by using the operating unit 143 to operate the feeder selection region B3, the operator can input the command to select the feeder 24F from among the production factors PF. By using the operating unit 143 to operate the nozzle selection region B4, the operator can input the command to select the suction nozzle 2511 from among the production factors PF. By using the operating unit 143 to operate the head selection region B5, the operator can input the command to select the loading head 251 from among the production factors PF.

The component 24P, the feeder 24F, the suction nozzle 2511, and the loading head 251 that constitute the production factors PF identified by the production factor information D1 associated with the suction error data set DPES can be a generating factor for the suction error in the suction nozzle 2511 of the mounting machine 12. That is, the posture of the component 24P supplied by the feeder 24F, the shape of the component, and the like affect the suctioning and holding performance of the component 24P by the suction nozzle 2511. Operating characteristics of the suction nozzle 2511 and the loading head 251, and the like also affect the suctioning and holding performance of the component 24P by the suction nozzle 2511. Since the suction error data set DPES corresponding to the production factor PF indicated by the factor selection command input via the operating unit 143 is displayed in the display unit 142, the operator can confirm the generating factor for the suction error in the suction nozzle 2511 by using the amount of loss of the component 24P caused by the suction error as an indicator. After confirming the generating factor for the suction error, the operator can take appropriate measures against the generating factor.

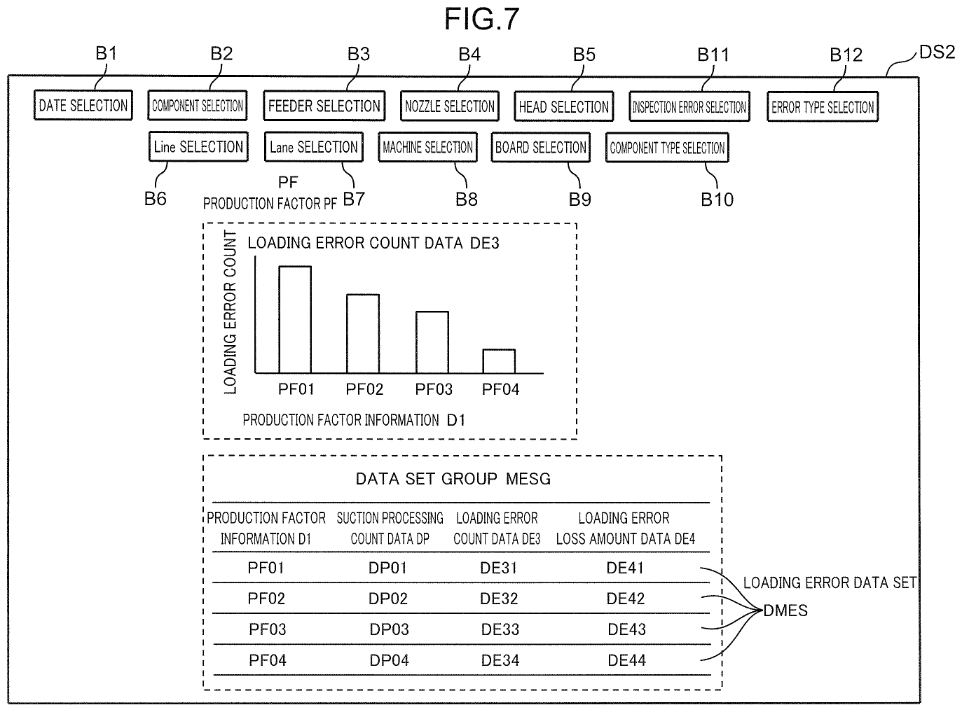

When a loading error display command to display data about the loading error and a factor selection command to select any one of the component 24P, the feeder 24F, the suction nozzle 2511, and the loading head 251 that constitute the production factors PF are input via the operating unit 143, the display control unit 1453 causes the display unit 142 to display a display screen DS2 as shown in FIG. 7. Specifically, the display control unit 1453 controls the display unit 142 such that a loading error data set DMES with the loading error count data DE3 and the loading error loss amount data DE4 associated with the production factor information D1 corresponding to the production factor PF indicated by the factor selection command as one pair is displayed in the display screen DS2. At this time, the display control unit 1453 causes the display screen DS2 to display the loading error data set DMES in which the production factor information D1, the suction processing count data DP, the loading error count data DE3, and the loading error loss amount data DE4 are associated with one another.

For example, when the factor selection command is a command to select the component 24P, the display control unit 1453 causes the display screen DS2 to display the loading error data set DMES with the loading error count data DE3 and the loading error loss amount data DE4 associated with the component information D11 to identify the component 24P as one set. Similarly, when the factor selection command is a command to select the feeder 24F, the display control unit 1453 causes the display screen DS2 to display the loading error data set DMES with the loading error count data DE3 and the loading error loss amount data DE4 associated with the feeder information D12 to identify the feeder 24F as one set. When the factor selection command is a command to select the suction nozzle 2511, the display control unit 1453 causes the display screen DS2 to display the loading error data set DMES with the loading error count data DE3 and the loading error loss amount data DE4 associated with the nozzle information D13 to identify the suction nozzle 2511 as one set. When the factor selection command is a command to select the loading head 251, the display control unit 1453 causes the display screen DS2 to display the loading error data set DMES with the loading error count data DE3 and the loading error loss amount data DE4 associated with the head information D14 to identify the loading head 251 as one set.

At this time, as shown in FIG. 7, the display control unit 1453 may control the display unit 142 such that the loading error count data DE3 or the loading error loss amount data DE4, and the loading error data set DMES are displayed simultaneously in the display screen DS2.

The suction state of the component 24P by the suction nozzle 2511 affects the loading state of the component 24P on the component loading board PPA. That is, the suction error and the loading error are correlated with each other. Therefore, the component 24P, the feeder 24F, the suction nozzle 2511, and the loading head 251 that constitute the production factors PF that can be a generating factor for the suction error can be a generating factor for the loading error on the component loading board PPA obtained by the mounting machine 12. Since the loading error data set DMES corresponding to the production factor PF indicated by the factor selection command input via the operating unit 143 is displayed in the display unit 142, the operator can confirm the generating factor for the loading error on the component loading board PPA obtained by the mounting machine 12 by using the amount of loss of the component 24P caused by the loading error as an indicator. After confirming the generating factor for the loading error, the operator can take appropriate measures against the generating factor.

A plurality of pieces of production factor information D1 may be set for each production factor PF used in the production of the component loading board PPA by the mounting machine 12. That is, in the production of the component loading board PPA, when the plurality of components 24P, the plurality of feeders 24F, the plurality of suction nozzles 2511, and the plurality of loading heads 251 are used, the plurality of pieces of production factor information D1 is set for each production factor PF. In this case, the plurality of pieces of component information D11 is set to identify the plurality of components 24P. Similarly, the plurality of pieces of feeder information D12 is set to identify the plurality of feeders 24F. The plurality of pieces of nozzle information D13 is set to identify the plurality of suction nozzles 2511. The plurality of pieces of head information D14 is set to identify the plurality of loading heads 251.

When the plurality of pieces of production factor information D1 is set for each production factor PF, the display control unit 1453 controls the display unit 142 such that a data set group PESG of the plurality of suction error data sets DPES or a data set group MESG of the plurality of loading error data sets DMES each associated with the plurality of pieces of production factor information D1 for identifying the production factor PF is displayed in correspondence with the production factor PF indicated by the factor selection command input via the operating unit 143 (FIGS. 6 and 7).

As shown in FIG. 6, when the data set group PESG of the plurality of suction error data sets DPES is displayed in the display unit 142, the operator can confirm the generating factor for the suction error in the suction nozzle 2511 by using the amount of loss of the component 24P caused by the suction error as an indicator while contrasting the plurality of suction error data sets DPES each associated with the plurality of pieces of production factor information D1. Meanwhile, as shown in FIG. 7, when the data set group MESG of the plurality of loading error data sets DMES is displayed in the display unit 142, the operator can confirm the generating factor for the loading error on the component loading board PPA obtained by the mounting machine 12 by using the amount of loss of the component 24P caused by the loading error as an indicator while contrasting the plurality of loading error data sets DMES each associated with the plurality of pieces of production factor information D1.

The display control unit 1453 controls the display unit 142 such that the plurality of suction error data sets DPES that constitutes the data set group PESG is displayed in order of the amount of loss of the component 24P. This allows workability to be improved when the operator confirms the generating factor for the suction error based on the data set group PESG displayed in the display unit 142. Similarly, the display control unit 1453 controls the display unit 142 such that the plurality of loading error data sets DMES that constitutes the data set group MESG is displayed in order of the amount of loss of the component 24P. This allows workability to be improved when the operator confirms the generating factor for the loading error based on the data set group MESG displayed in the display unit 142.

Note that the display control unit 1453 may control the display unit 142 such that the plurality of suction error data sets DPES that constitutes the data set group PESG is displayed in order of the occurrence count of suction errors. In this case as well, this allows workability to be improved when the operator confirms the generating factor for the suction error based on the data set group PESG displayed in the display unit 142. Similarly, the display control unit 1453 may control the display unit 142 such that the plurality of loading error data sets DMES that constitutes the data set group MESG is displayed in order of the occurrence count of loading errors. In this case as well, this allows workability to be improved when the operator confirms the generating factor for the loading error based on the data set group MESG displayed in the display unit 142.

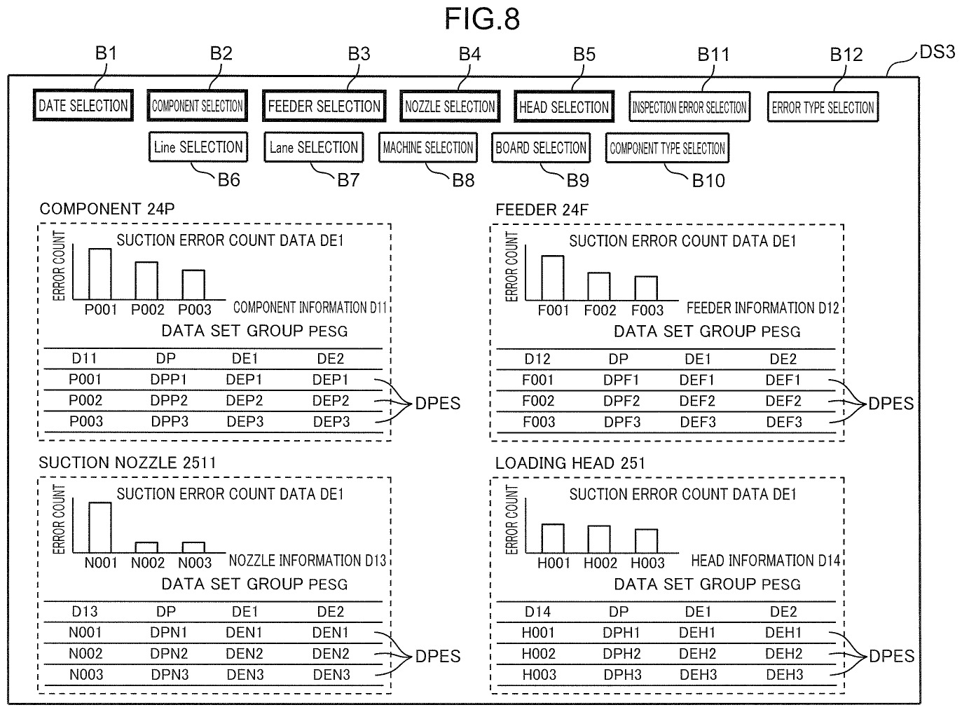

As the factor selection command, when a command to select the plurality of production factors PF from among the component 24P, the feeder 24F, the suction nozzle 2511, and the loading head 251 that constitute the production factors PF is input via the operating unit 143, the display control unit 1453 causes the display unit 142 to display a display screen DS3 as shown in FIG. 8. Note that FIG. 8 shows an example where four production factors PF including the component 24P, the feeder 24F, the suction nozzle 2511, and the loading head 251 are selected.

Specifically, when the suction error display command to display data about the suction error and the command to select the plurality of production factors PF are input via the operating unit 143, the display control unit 1453 controls the display unit 142 such that the data set groups PESG of the suction error data sets DPES corresponding to the plurality of production factors PF are displayed simultaneously in the display screen DS3 in a state divided into the plurality of production factors PF. In the example of FIG. 8, the display control unit 1453 causes the display screen DS3 to display the data set groups PESG of the suction error data sets DPES corresponding to the component 24P, the feeder 24F, the suction nozzle 2511, and the loading head 251. When the data set groups PESG of the plurality of suction error data sets DPES corresponding to the plurality of production factors PF are simultaneously displayed in the display unit 142, the operator can confirm the generating factor for the suction error in the suction nozzle 2511 by using the amount of loss of the component 24P caused by the suction error as an indicator while contrasting the data set groups PESG corresponding to the plurality of production factors PF.

Meanwhile, when the loading error display command to display data about the loading error and the command to select the plurality of production factors PF are input via the operating unit 143, the display control unit 1453 controls the display unit 142 such that the data set groups MESG of the loading error data sets DMES corresponding to the plurality of production factors PF are displayed simultaneously in a state divided into the plurality of production factors PF. In this case, the operator can confirm the generating factor for the loading error on the component loading board PPA obtained by the mounting machine 12 by using the amount of loss of the component 24P caused by the loading error as an indicator while comparing the data set groups MESG corresponding to the plurality of production factors PF.

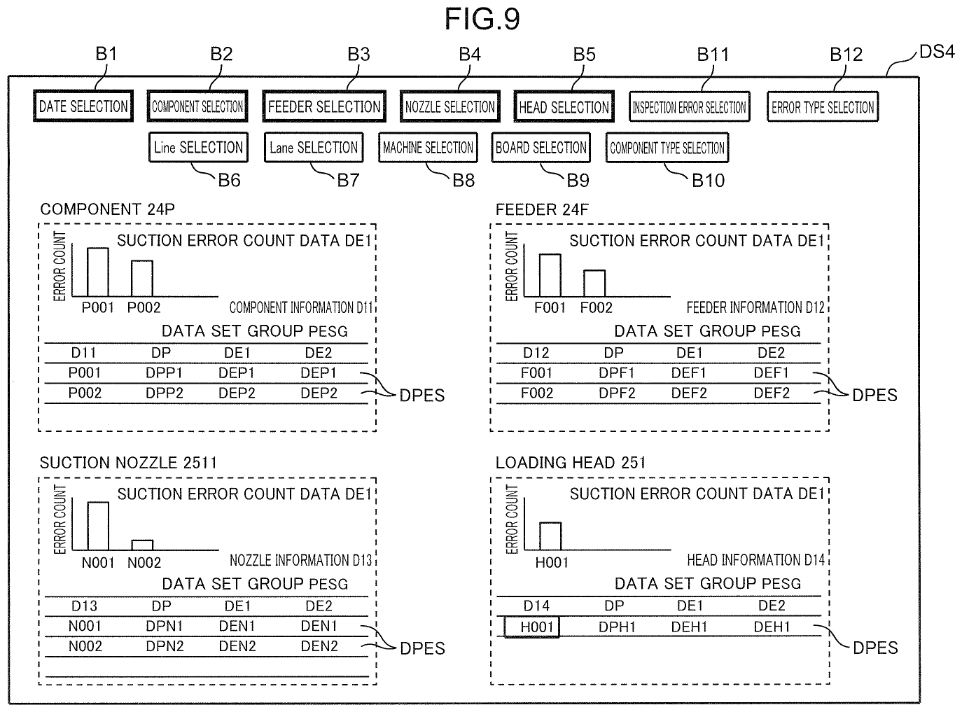

With the data set groups PESG of the suction error data sets DPES corresponding to the plurality of production factors PF simultaneously displayed in the display unit 142, when a command to select one piece of the production factor information D1 from the plurality of pieces of production factor information D1 set for each of the plurality of production factors PF is input via the operating unit 143, the display control unit 1453 causes the display unit 142 to display a display screen DS4 as shown in FIG. 9. Note that FIG. 9 shows an example in which one piece of head information D14 is selected from the plurality of pieces of head information D14 with the data set groups PESG of the suction error data sets DPES corresponding to the component 24P, the feeder 24F, the suction nozzle 2511, and the loading head 251 displayed simultaneously.

Specifically, when a command to select one piece of production factor information D1 from the plurality of pieces of production factor information D1 set for the plurality of production factors PF is input via the operating unit 143, the display control unit 1453 controls the display unit 142 such that only the suction error data set DPES related to the one piece of production factor information D1 is displayed. In this way, when only the suction error data set DPES related to one piece of production factor information D1 selected by an input operation on the operating unit 143 is displayed in the display unit 142, the operator can confirm the generating factor for the suction error in the suction nozzle 2511 by using the amount of loss of the component 24P caused by the suction error as an indicator while focusing on the production factor PF identified by the one piece of production factor information D1.

Meanwhile, with the data set groups MESG of the loading error data set DMES corresponding to the plurality of production factors PF simultaneously displayed in the display unit 142, assume a case where a command to select one piece of production factor information D1 from the plurality of pieces of production factor information D1 set for the plurality of production factors PF is input via the operating unit 143. In this case, the display control unit 1453 controls the display unit 142 such that only the loading error data set DMES related to the one piece of production factor information D1 is displayed. In this way, when only the loading error data set DMES related to one piece of production factor information D1 selected by an input operation on the operating unit 143 is displayed in the display unit 142, the operator can confirm the generating factor for the loading error on the component loading board PPA obtained by the mounting machine 12 by using the amount of loss of the component 24P caused by the loading error as an indicator while focusing on the production factor PF identified by the one piece of production factor information D1.

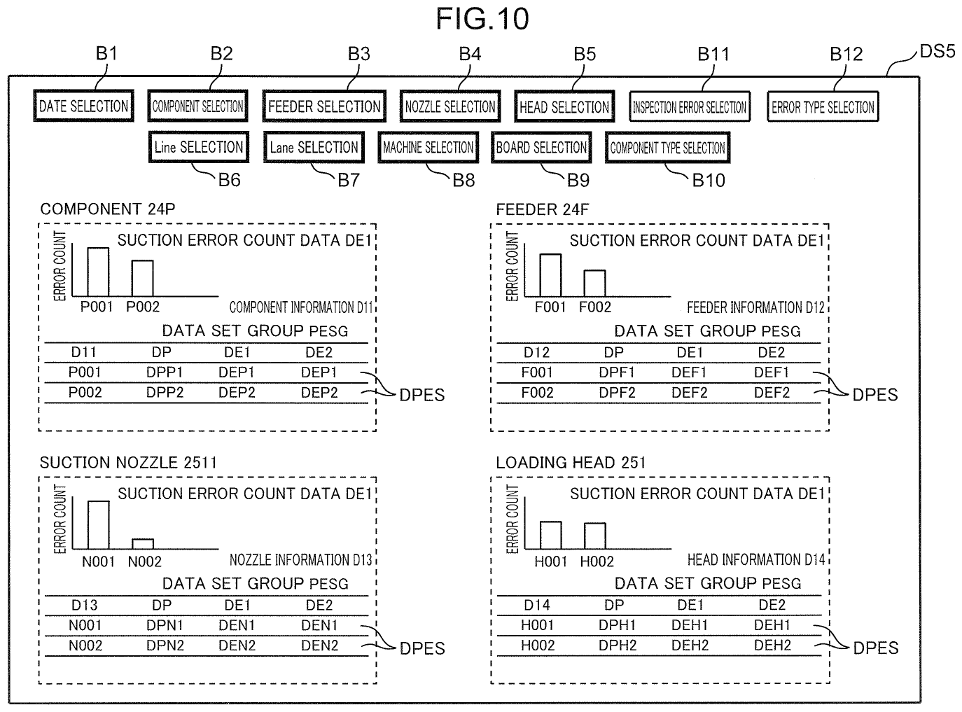

As shown in FIG. 10, in the present embodiment, the display control unit 1453 controls the display unit 142 such that a Line selection region B6, a Lane selection region B7, a machine selection region B8, a board selection region B9, and a component type selection region B10 that allow input operations via the operating unit 143 are set in a display screen DS5. The Line selection region B6, the Lane selection region B7, the machine selection region B8, the board selection region B9, and the component type selection region B10 that are set in the display screen DS5 are regions for inputting the command to set a narrowing condition for narrowing the plurality of pieces of production factor information D1 set for each production factor PF.

By using the operating unit 143 to operate the Line selection region B6, the operator can input a command to select one mounting line 11 from the plurality of mounting lines 11 that constitute the component mounting line 10 as the narrowing condition. That is, when the narrowing condition to select one mounting line 11 is set by the operation of the Line selection region B6 using the operating unit 143, the plurality of pieces of production factor information D1 set for the production factors PF is narrowed down to the production factor information D1 related to the one mounting line 11.

When the mounting machine 12 equipped with a dual-lane type board conveyance mechanism including two conveyors 23 is applied to the production of the component loading board PPA, the operator can input a command to set selecting one lane of the dual lanes as the narrowing condition by using the operating unit 143 to operate the Lane selection region B7. That is, when the narrowing condition to select one lane is set by the operation of the Lane selection region B7 using the operating unit 143, the plurality of pieces of production factor information D1 set for the production factors PF is narrowed down to the production factor information D1 related to the one lane.

By using the operating unit 143 to operate the machine selection region B8, the operator can input a command to set selecting one mounting machine 12 from the plurality of mounting machines 12 on the component mounting line 10 as the narrowing condition. That is, when the narrowing condition to select one mounting machine 12 is set by the operation of the machine selection region B8 using the operating unit 143, the plurality of pieces of production factor information D1 set for the production factors PF is narrowed down to the production factor information D1 related to the one mounting machine 12.

By using the operating unit 143 to operate the board selection region B9, the operator can input a command to set selecting one board PP from the plurality of boards PP used in the production of the component loading board PPA by the mounting machine 12 as the narrowing condition. That is, when the narrowing condition to select one board PP is set by the operation of the board selection region B9 using the operating unit 143, the plurality of pieces of production factor information D1 set for the production factors PF is narrowed down to the production factor information D1 related to the one board PP.

By using the operating unit 143 to operate the component type selection region B10, the operator can input a command to set selecting one component type from the plurality of component types of the component 24P used in the production of the component loading board PPA by the mounting machine 12 as the narrowing condition. That is, when the narrowing condition to select one component type is set by the operation of the component type selection region B10 using the operating unit 143, the plurality of pieces of production factor information D1 set for the production factors PF is narrowed down to the production factor information D1 related to the one component type.

As shown in FIG. 10, with the data set groups PESG of the plurality of suction error data sets DPES associated with the plurality of pieces of production factor information D1 displayed in the display unit 142, when the command to set the narrowing condition for narrowing down the plurality of pieces of production factor information D1 set for the production factors PF is input via the operating unit 143, the display control unit 1453 controls the display unit 142 such that the data set groups PESG including the specific suction error data sets DPES associated with the production factor information D1 that satisfies the narrowing condition out of the plurality of pieces of production factor information D1 is displayed. This allows the suction error data sets DPES that constitute the data set groups PESG displayed in the display unit 142 to be narrowed down according to the narrowing condition. Therefore, workability when the operator confirms the generating factor for the suction error can be improved.

Similarly, with the data set groups MESG of the plurality of loading error data sets DMES associated with the plurality of pieces of production factor information D1 displayed in the display unit 142, when the command to set the narrowing condition for narrowing down the plurality of pieces of production factor information D1 set for the production factors PF is input via the operating unit 143, the display control unit 1453 controls the display unit 142 such that the data set groups MESG including the specific loading error data sets DMES associated with the production factor information D1 that satisfies the narrowing condition out of the plurality of pieces of production factor information D1 is displayed. This allows the loading error data sets DMES that constitute the data set groups MESG displayed in the display unit 142 to be narrowed down according to the narrowing condition. Therefore, workability when the operator confirms the generating factor for the loading error can be improved.

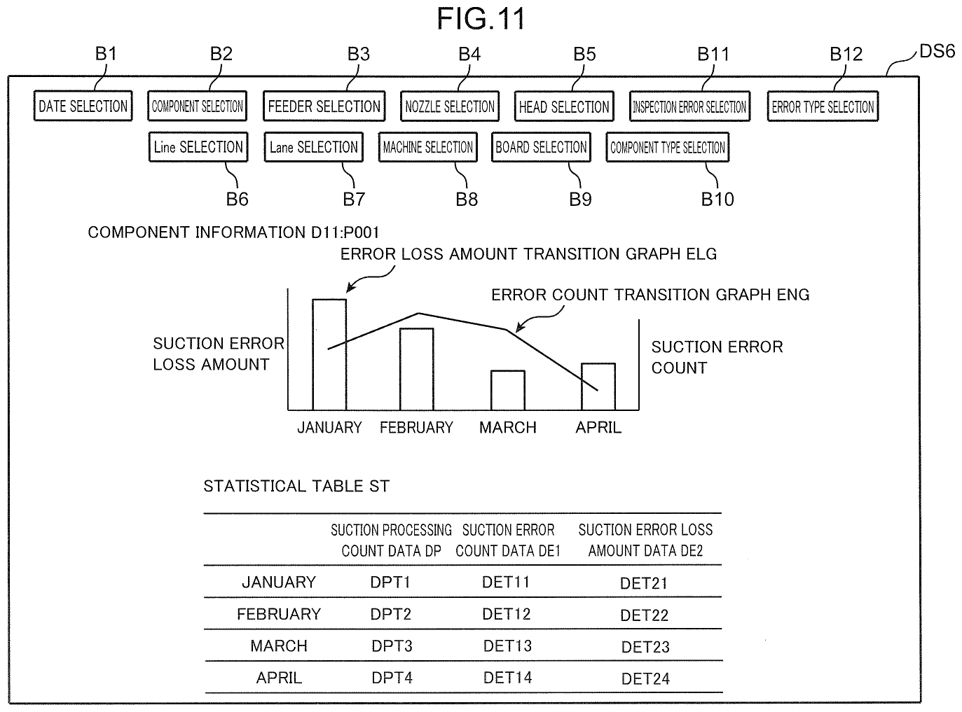

Next, with the data set groups PESG of the plurality of suction error data sets DPES associated with the plurality of pieces of production factor information D1 displayed in the display unit 142, assume a case where a command to display temporal transition of data associated with one piece of production factor information D1 out of the plurality of pieces of production factor information D1 is input via the operating unit 143. In this case, as shown in FIG. 11, the display control unit 1453 controls the display unit 142 such that an error count transition graph ENG indicating temporal transition of the suction error count data DE1 associated with the one piece of production factor information D1 and an error loss amount transition graph ELG indicating temporal transition of the suction error loss amount data DE2 are displayed in a display screen DS6. In the example in FIG. 11, the error count transition graph ENG including a line graph indicating transition of the suction error count data DE1, and the error loss amount transition graph ELG including a bar graph indicating transition of the suction error loss amount data DE2 by month in January, February, March, and April are displayed in the display unit 142. Note that as shown in FIG. 11, the display control unit 1453 may control the display unit 142 such that a statistical table ST in which the suction processing count data DP, the suction error count data DE1, and the suction error loss amount data DE2 are associated with one another is displayed simultaneously with the error count transition graph ENG and the error loss amount transition graph ELG.

Similarly, with the data set groups MESG of the plurality of loading error data sets DMES associated with the plurality of pieces of production factor information D1 displayed in the display unit 142, assume a case where a command to display temporal transition of data associated with one piece of production factor information D1 out of the plurality of pieces of production factor information D1 is input via the operating unit 143. In this case, the display control unit 1453 controls the display unit 142 such that the error count transition graph ENG indicating temporal transition of the loading error count data DE3 associated with the one piece of production factor information D1 and the error loss amount transition graph ELG indicating temporal transition of the loading error loss amount data DE4 are displayed.

The operator can check the temporal transition of the suction error count data DE1 or the loading error count data DE3 based on the error count transition graph ENG displayed in the display unit 142, and can check the temporal transition of the suction error loss amount data DE2 or the loading error loss amount data DE4 based on the error loss amount transition graph ELG.

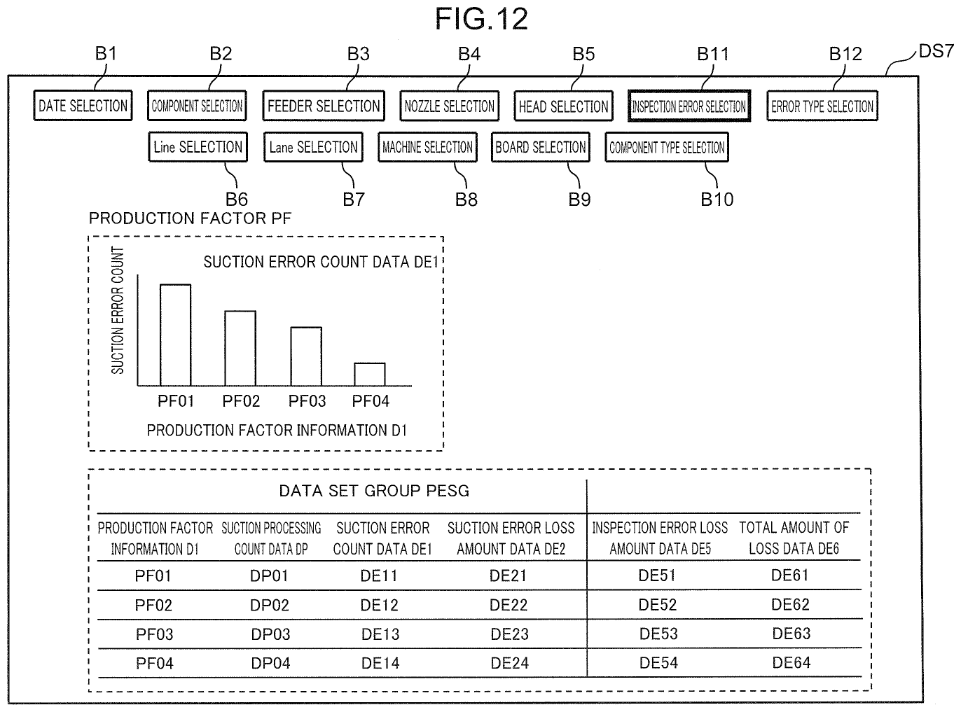

As shown in FIG. 12, in the present embodiment, the display control unit 1453 controls the display unit 142 such that an inspection error selection region B11 that enables input operations via the operating unit 143 is set in a display screen DS7. The inspection error selection region B11 set in the display screen DS7 is a region for inputting a command to display data about the waste component indicating the component discarded together with the component loading board PPA due to the inspection error in the inspection device 13. By using the operating unit 143 to operate the inspection error selection region B11, the operator can input the command to display data about the waste component discarded together with the component loading board PPA due to the inspection error in the inspection device 13.

When the command to display data about the waste component discarded together with the component loading board PPA is input via the operating unit 143, the display control unit 1453 controls the display unit 142 such that the inspection error loss amount data DE5 generated by the data generating unit 1452 in association with the inspection error information D4 is displayed. Based on the inspection error loss amount data DE5 displayed in the display unit 142, the operator can confirm the generating factor for the suction error or loading error while focusing on the amount of loss of the waste component discarded together with the component loading board PPA due to the inspection error in the inspection device 13.

In FIG. 12, with the data set group PESG of the plurality of suction error data sets DPES associated with the plurality of pieces of production factor information D1 displayed in the display unit 142, an example in which the command to display data about the waste component discarded together with the component loading board PPA is input via the operating unit 143 is shown. In this case, the display control unit 1453 controls the display unit 142 such that the data set group PESG of the plurality of suction error data sets DPES and the inspection error loss amount data DE5 are displayed simultaneously. At this time, the display control unit 1453 may control the display unit 142 such that total amount of loss data DE6 expressed in the total amount of the amount of loss indicated by the suction error loss amount data DE2 and the amount of loss indicated by the inspection error loss amount data DE5 is displayed. The display control unit 1453 may control the display unit 142 such that the data set group MESG of the plurality of loading error data sets DMES and the inspection error loss amount data DE5 are displayed simultaneously.

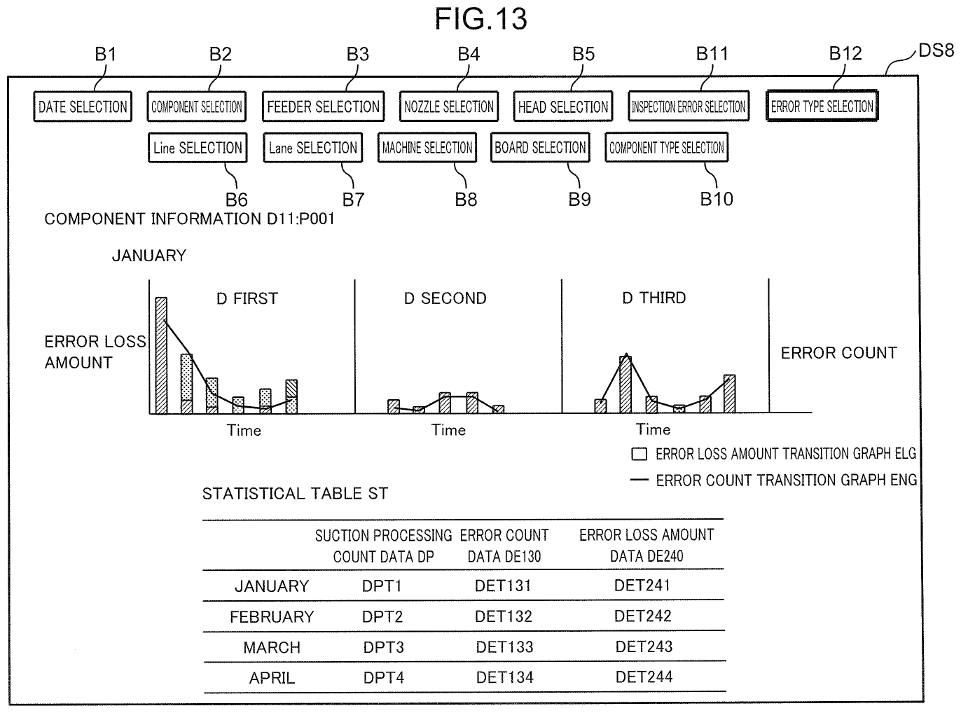

As shown in FIG. 13, in the present embodiment, the display control unit 1453 controls the display unit 142 such that an error type selection region B12 that enables input operations via the operating unit 143 is set in a display screen DS8. The error type selection region B12 set in the display screen DS8 is a region for inputting a command to display data for each error type of the suction error or loading error. By using the operating unit 143 to operate the error type selection region B12, the operator can input the command to display data for each error type of the suction error or loading error.

When the command to display data for each type of the suction error is input via the operating unit 143, the display control unit 1453 controls the display unit 142 such that the suction error loss amount data DE2 is displayed in a state divided into the error types. When the command to display data for each error type of the loading error is input via the operating unit 143, the display control unit 1453 controls the display unit 142 such that the loading error loss amount data DE4 is displayed in a state divided into the error types. This allows the operator to confirm the generating factor for the suction error or loading error while focusing on the amount of loss of the component 24P for each error type.

Note that in FIG. 13, with the error count transition graph ENG of the suction error count data DE1 or the loading error count data DE3 displayed, an example is displayed in which the suction error loss amount data DE2 or the loading error loss amount data DE4 that constitutes the error loss amount transition graph ELG is displayed in a state divided into the error types.

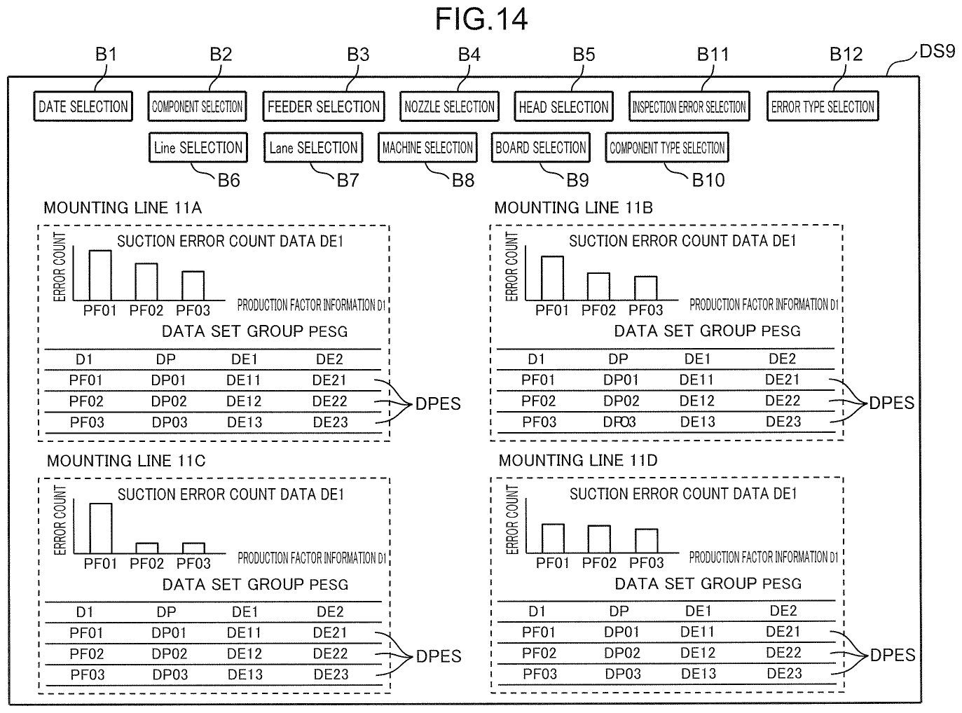

Next, with the data set groups PESG of the plurality of suction error data sets DPES associated with the plurality of pieces of production factor information D1 displayed in the display unit 142, assume a case where a command to display the data set groups PESG for the plurality of mounting lines 11 is input via the operating unit 143. In this case, as shown in FIG. 14, the display control unit 1453 controls the display unit 142 such that the data set groups PESG corresponding to the plurality of mounting lines 11 are displayed simultaneously in display regions individually set for the plurality of mounting lines 11 in a display screen DS9. This allows the operator to confirm the generating factor for the suction error by using the amount of loss of the component 24P caused by the suction error as an indicator while contrasting the data set groups PESG of the suction error data sets DPES corresponding to the plurality of mounting lines 11.

Similarly, with the data set groups MESG of the plurality of loading error data sets DMES associated with the plurality of pieces of production factor information D1 displayed in the display unit 142, assume a case where a command to display the data set groups MESG for the plurality of mounting lines 11 is input via the operating unit 143. In this case, the display control unit 1453 controls the display unit 142 such that the data set groups MESG corresponding to the plurality of mounting lines 11 are displayed simultaneously in display regions individually set for the plurality of mounting lines 11. This allows the operator to confirm the generating factor for the loading error by using the amount of loss of the component 24P caused by the loading error as an indicator while contrasting the data set groups MESG of the loading error data sets DMES corresponding to the plurality of mounting lines 11.

Note that the above-described specific embodiment mainly includes the disclosure having the following configurations.

A component mounting system according to one aspect of the present disclosure includes a component mounting line including at least a mounting machine that produces a component loading board with a component loaded; and a management device configured to manage production of the component loading board in the mounting machine. The mounting machine includes a feeder that supplies the component: a loading head including a suction nozzle that suctions the component to obtain the component loading board by loading the component suctioned by the suction nozzle on a board; and a suction state recognition unit configured to recognize a suction state of the component by the suction nozzle and output suction error information when a suction error indicating an abnormality in the suction state occurs. The management device includes a storage unit configured to accumulate and store management data in which production factor information to identify production factors indicated by one of the component, the feeder, the suction nozzle, and the loading head used in the production of the component loading board is associated with the suction error information for each suction of the component by the suction nozzle: a data generating unit configured to generate error count data about an occurrence count of the suction error and error loss amount data about an amount of loss of the component caused by the occurrence of the suction error in association with each piece of the production factor information based on a data group of the management data accumulated and stored in the storage unit: a display unit that enables display of various data: an operating unit to which a command about a display mode of the display unit is input; and a display control unit configured to control the display unit in response to the command input into the operating unit. When a suction error display command to display data about the suction error and a factor selection command to select one of the production factors are input via the operating unit, the display control unit is configured to control the display unit such that an error data set is displayed with the error count data and the error loss amount data associated with the production factor information corresponding to the production factor indicated by the factor selection command as one set.

This component mounting system is provided with the management device for managing production of the component loading board in the mounting machine. This management device includes the storage unit, the data generating unit, and the display control unit. The storage unit accumulates and stores the management data in which the production factor information to identify the production factors used in the production of the component loading board by the mounting machine and the suction error information output from the suction state recognition unit of the mounting machine are associated with one another. The data generating unit generates the error count data and the error loss amount data about the suction error in association with each piece of the production factor information based on the data group of the management data. The display control unit controls the display unit such that the error data set is displayed with the error count data and the error loss amount data about the suction error associated with the production factor information of the production factor indicated by the factor selection command input via the operating unit as one set.

The component, the feeder, the suction nozzle, and the loading head that constitute the production factors identified by the production factor information associated with the error data set can be a generating factor for the suction error in the suction nozzle of the mounting machine. That is, the posture of the component and the shape of the component supplied by the feeder, and the like affect the suctioning and holding performance of the component by the suction nozzle. Operating characteristics of the suction nozzle and the loading head, and the like also affect the suctioning and holding performance of the component by the suction nozzle. Since the error data set about the suction error corresponding to the production factor indicated by the factor selection command input via the operating unit is displayed in the display unit, the operator can confirm the generating factor for the suction error in the suction nozzle by using the amount of loss of the component caused by the suction error as an indicator.

A component mounting system according to another aspect of the present disclosure includes a component mounting line including a mounting machine that produces a component loading board with a component mounted, and an inspection device that inspects a loading state of the component on the component loading board; and a management device configured to manage production of the component loading board in the mounting machine. The mounting machine includes a feeder that supplies the component; and a loading head including a suction nozzle that suctions the component to obtain the component loading board by loading the component suctioned by the suction nozzle on a board. The inspection device is configured to output loading error information when a loading error indicating an abnormality in the loading state of the component on the component loading board occurs. The management device includes a storage unit configured to accumulate and store management data in which production factor information to identify production factors indicated by one of the component, the feeder, the suction nozzle, and the loading head used in the production of the component loading board is associated with the loading error information for each suction of the component by the suction nozzle; and a data generating unit configured to generate error count data about an occurrence count of the loading error and error loss amount data about an amount of loss of the component caused by the occurrence of the loading error in association with each piece of the production factor information based on a data group of the management data accumulated and stored in the storage unit. Also, the management device includes a display unit that enables display of various data: an operating unit to which a command about a display mode of the display unit is input; and a display control unit configured to control the display unit in response to the command input into the operating unit. When a loading error display command to display data about the loading error and a factor selection command to select one of the production factors are input via the operating unit, the display control unit is configured to control the display unit such that an error data set is displayed with the error count data and the error loss amount data associated with the production factor information corresponding to the production factor indicated by the factor selection command as one set.

With this component mounting system, the display control unit can cause the display unit to display the error data set with the error count data and the error loss amount data about the loading error associated with the production factor information of the production factor indicated by the factor selection command input via the operating unit as one set. Since the error data set about the loading error corresponding to the production factor indicated by the factor selection command input via the operating unit is displayed in the display unit, the operator can confirm the generating factor for the loading error on the component loading board obtained by the mounting machine by using the amount of loss of the component caused by the loading error as an indicator.

In the component mounting system, when the plurality of pieces of production factor information is set for the production factors, the display control unit is configured to control the display unit such that a data set group of a plurality of the error data sets associated with the plurality of pieces of production factor information is displayed.

A plurality of pieces of production factor information may be set for each of the production factors used for production of the component loading board by the mounting machine. That is, in the production of the component loading board, when the plurality of components, the plurality of feeders, the plurality of suction nozzles, and the plurality of loading heads are used, the plurality of pieces of production factor information is set for each of the production factors. In this case, the display control unit controls the display unit such that the data set group of the plurality of error data sets associated with the plurality of pieces of production factor information for identifying the production factor is displayed in correspondence with the production factor indicated by the factor selection command input via the operating unit.

When the data set group of the plurality of error data sets about the suction error is displayed in the display unit, the operator can confirm the generating factor for the suction error in the suction nozzle by using the amount of loss of the component caused by the suction error as an indicator while contrasting the plurality of error data sets associated with the plurality of pieces of production factor information. Meanwhile, when the data set group of the plurality of error data sets about the loading error is displayed in the display unit, the operator can confirm the generating factor for the loading error on the component loading board obtained by the mounting machine by using the amount of loss of the component caused by the loading error as an indicator while contrasting the plurality of error data sets associated with the plurality of pieces of production factor information.

In the component mounting system, when a command to select a plurality of the production factors from the production factors is input via the operating unit as the factor selection command, the display control unit is configured to control the display unit such that a plurality of the data set groups corresponding to the plurality of production factors is displayed simultaneously in a state divided into the plurality of production factors.

In this aspect, the display control unit causes the display unit to simultaneously display the plurality of data set groups corresponding to the plurality of production factors selected by an input operation on the operating unit in a state divided into the plurality of production factors. When the data set groups of the plurality of error data sets about the suction error corresponding to the plurality of production factors are simultaneously displayed in the display unit, the operator can confirm the generating factor for the suction error in the suction nozzle by using the amount of loss of the component caused by the suction error as an indicator while contrasting the data set groups corresponding to the plurality of production factors. Meanwhile, when the data set groups of the plurality of error data sets about the loading error corresponding to the plurality of production factors is displayed in the display unit, the operator can confirm the generating factor for the loading error on the component loading board obtained by the mounting machine by using the amount of loss of the component caused by the loading error as an indicator while contrasting the data set groups corresponding to the plurality of production factors.

In the component mounting system, with the data set groups respectively corresponding to the plurality of production factors simultaneously displayed in the display unit, when a command to select one piece of production factor information from among the plurality of pieces of production factor information set for the plurality of production factors is input via the operating unit, the display control unit is configured to control the display unit such that only the error data set related to the one piece of production factor information is displayed.

In this aspect, when the command to select one piece of production factor information from the plurality of pieces of production factor information set for the plurality of production factors is input via the operating unit, the display control unit causes the display unit to display only the error data set related to the one piece of production factor information. When only the error data set about the suction error related to the one piece of production factor information selected by an input operation on the operating unit is displayed in the display unit, the operator can confirm the generating factor for the suction error in the suction nozzle by using the amount of loss of the component caused by the suction error as an indicator while focusing on the production factor identified by the one piece of production factor information. Meanwhile, when only the error data set about the loading error related to the one piece of production factor information selected by an input operation on the operating unit is displayed in the display unit, the operator can confirm the generating factor for the loading error on the component loading board obtained by the mounting machine by using the amount of loss of the component caused by the loading error as an indicator while focusing on the production factor identified by the one piece of production factor information.

In the component mounting system, when a command to set a narrowing condition for narrowing the plurality of pieces of production factor information set for the production factors is input via the operating unit, the display control unit is configured to control the display unit such that the data set group including the specific error data set associated with the production factor information that satisfies the narrowing condition among the plurality of pieces of production factor information is displayed.

In this aspect, when the command to set the narrowing condition for narrowing the plurality of pieces of production factor information set for the production factors is input via the operating unit, the display control unit causes the display unit to display the data set group including the specific error data set associated with the production factor information that satisfies the narrowing condition. This allows the error data sets that constitute the data set groups displayed in the display unit to be narrowed down according to the narrowing condition. Therefore, workability when the operator confirms the generating factor for the suction error or the loading error can be improved.

In the component mounting system, with the data set group associated with the plurality of pieces of production factor information displayed in the display unit, when a command to display temporal transition of data associated with one piece of production factor information among the plurality of pieces of production factor information is input via the operating unit, the display control unit is configured to control the display unit such that an error count transition graph indicating temporal transition of the error count data associated with the one piece of production factor information and an error loss amount transition graph indicating temporal transition of the error loss amount data are displayed.

In this aspect, when the command to display the temporal transition of data associated with one piece of production factor information among the plurality of pieces of production factor information set for the plurality of production factors is input via the operating unit, the display control unit causes the display unit to display the error count transition graph and the error loss amount transition graph. This allows the operator to check the temporal transition of the error count data based on the error count transition graph, and to check the temporal transition of the error loss amount data based on the error loss amount transition graph.

In the component mounting system, the display control unit is configured to control the display unit such that the plurality of error data sets that constitute the data set group is displayed in order of the amount of loss of the component.

In this aspect, the display control unit displays the plurality of error data sets that constitute the data set group in order of the amount of loss of the component. This allows workability to be improved when the operator confirms the generating factor for the suction error or the loading error based on the data set group displayed in the display unit.

In the component mounting system, the display control unit is configured to control the display unit such that the plurality of error data sets that constitute the data set group is displayed in order of the occurrence count of the error.

In this aspect, the display control unit displays the plurality of error data sets that constitute the data set group in order of the occurrence count of the suction error or the loading error. This allows workability to be improved when the operator confirms the generating factor for the suction error or the loading error based on the data set group displayed in the display unit.

In the component mounting system, the storage unit is configured, when there is a waste component indicating the component discarded together with the component loading board due to an inspection error in the inspection device, to accumulate and store the management data to which inspection error information for identifying the waste component is added. The data generating unit is configured, when the inspection error information is added to the management data, to generate inspection error loss amount data about the amount of loss of the waste component in association with the inspection error information. When a command to display data about the waste component is input via the operating unit, the display control unit is configured to control the display unit such that the inspection error loss amount data is displayed.

For example, when the loading error information is output from the inspection device, if it is possible to replace the component of the loading error with a new component, the operator may discard the component of the loading error and execute work to repair the component loading board by replacement with a new component. Meanwhile, if it is impossible to replace the component of the loading error with a new component, the operator discards the component loading board. In this case, all the components on the component loading board are discarded. When such a command to display data about the waste component indicating the component discarded together with the component loading board due to the inspection error in the inspection device is input via the operating unit, the display control unit causes the display unit to display the inspection error loss amount data associated with the inspection error information for identifying the waste component. Based on the inspection error loss amount data displayed in the display unit, the operator can confirm the generating factor for the suction error or the loading error while focusing on the amount of loss of the waste component discarded together with the component loading board due to the inspection error in the inspection device.

In the component mounting system, the data generating unit is configured to generate the error loss amount data in a state divided into an error type indicating a type of the error. When a command to display data for each error type is input via the operating unit, the display control unit is configured to control the display unit such that the error loss amount data is displayed in a state divided into the error type.

As the suction error, there is a plurality of types of suction error about a component fall indicating a fall of the component from the suction nozzle, suction position offset of the component with respect to the suction nozzle, suction posture of the component with respect to the suction nozzle, and the like. As the loading error, there is a plurality of types of loading error about the loading posture or loading position offset of the component on the component loading board, coplanarity of the component loading board, the lead pitch, the lead width, and the number of leads of the component on the component loading board, and the like. When such a command to display data for each of the plurality of types of suction error type or loading error type is input via the operating unit, the display control unit causes the display unit to display the error loss amount data in a state divided into the error type. This allows the operator to confirm the generating factor for the suction error or the loading error while focusing on the amount of loss of the component for each error type.

In the component mounting system, the component mounting line includes a plurality of mounting lines. When a command to display the data set group for each of the plurality of mounting lines is input via the operating unit, the display control unit is configured to control the display unit such that the data set groups corresponding to the plurality of mounting lines are simultaneously displayed in display regions individually set for the plurality of mounting lines.

The display control unit displays the data set groups corresponding to the plurality of mounting lines simultaneously in display regions individually set for the plurality of mounting lines in the display unit. This allows the operator to confirm the generating factor for the suction error or loading error by using the amount of loss of the component caused by the suction error or loading error as an indicator while contrasting the data set groups corresponding to the plurality of mounting lines.

As described above, the present disclosure can provide a component mounting system capable of confirming the generating factor for the suction error in the suction nozzle of the mounting machine by using the amount of loss of the component caused by the suction error as an indicator.

1. A component mounting system comprising:
a component mounting line including at least a mounting machine that produces configured to produce a component loading board with a component loaded; and
a management device configured to manage production of the component loading board in the mounting machine,
wherein the mounting machine includes:
a feeder that supplies the component;
a loading head including a suction nozzle that suctions the component to obtain the component loading board by loading the component suctioned by the suction nozzle on a board; and
a suction state recognition unit configured to recognize a suction state of the component by the suction nozzle and output suction error information when a suction error indicating an abnormality in the suction state occurs,
the management device includes:
a storage configured to accumulate and store management data in which production factor information to identify production factors indicated by one of the component, the feeder, the suction nozzle, and the loading head used in the production of the component loading board is associated with the suction error information for each suction of the component by the suction nozzle;
a data generator configured to generate error count data about an occurrence count of the suction error and error loss amount data about an amount of loss of the component caused by the occurrence of the suction error in association with each piece of the production factor information based on a data group of the management data accumulated and stored in the storage;
a display configured to display various data;
an operating unit configured to input a command about a display mode of the display; and
a display controller configured to control the display in response to the command input into the operating unit, and
when a suction error display command to display data about the suction error and a factor selection command to select one of the production factors are input via the operating unit, the display controller is configured to control the display such that an error data set is displayed with the error count data and the error loss amount data associated with the production factor information corresponding to the production factor indicated by the factor selection command as one set.

2. A component mounting system comprising:
a component mounting line including a mounting machine that produces a component loading board with a component mounted, and an inspection device that inspects a loading state of the component on the component loading board; and
a management device configured to manage production of the component loading board in the mounting machine,
wherein the mounting machine includes:
a feeder that supplies the component; and
a loading head including a suction nozzle that suctions the component to obtain the component loading board by loading the component suctioned by the suction nozzle on a board,
the inspection device is configured to output loading error information when a loading error indicating an abnormality in the loading state of the component on the component loading board occurs,
the management device includes:
a storage configured to accumulate and store management data in which production factor information to identify production factors indicated by one of the component, the feeder, the suction nozzle, and the loading head used in the production of the component loading board is associated with the loading error information for each suction of the component by the suction nozzle;
a data generator configured to generate error count data about an occurrence count of the loading error and error loss amount data about an amount of loss of the component caused by the occurrence of the loading error in association with each piece of the production factor information based on a data group of the management data accumulated and stored in the storage;
a display configured to display various data;
an operating unit configured to input a command about a display mode of the display; and
a display controller configured to control the display in response to the command input into the operating unit, and
when a loading error display command to display data about the loading error and a factor selection command to select one of the production factors are input via the operating unit, the display controller is configured to control the display such that an error data set is displayed with the error count data and the error loss amount data associated with the production factor information corresponding to the production factor indicated by the factor selection command as one set.

3. The component mounting system according to claim 1, wherein when a plurality of pieces of production factor information is set for the production factors, the display controller is configured to control the display such that a data set group of a plurality of the error data sets associated with the plurality of pieces of production factor information is displayed.

4. The component mounting system according to claim 3, wherein when a command to select a plurality of the production factors from the production factors is input via the operating unit as the factor selection command, the display controller is configured to control the display such that a plurality of the data set groups corresponding to the plurality of production factors is displayed simultaneously in a state divided into the plurality of production factors.

5. The component mounting system according to claim 4, wherein with the data set groups respectively corresponding to the plurality of production factors simultaneously displayed in the display, when a command to select one piece of production factor information from among the plurality of pieces of production factor information set for the plurality of production factors is input via the operating unit, the display controller is configured to control the display such that only the error data set related to the one piece of production factor information is displayed.

6. The component mounting system according to claim 3, wherein when a command to set a narrowing condition for narrowing the plurality of pieces of production factor information set for the production factors is input via the operating unit, the display controller is configured to control the display unit such that the data set group including a specific error data set associated with the production factor information that satisfies the narrowing condition among the plurality of pieces of production factor information is displayed.

7. The component mounting system according to claim 3, wherein with the data set group associated with the plurality of pieces of production factor information displayed in the display, when a command to display temporal transition of data associated with one piece of production factor information among the plurality of pieces of production factor information is input via the operating unit, the display controller is configured to control the display such that an error count transition graph indicating temporal transition of the error count data associated with the one piece of production factor information and an error loss amount transition graph indicating temporal transition of the error loss amount data are displayed.

8. The component mounting system according to claim 3, wherein the display controller is configured to control the display such that the plurality of error data sets that constitute the data set group is displayed in order of the amount of loss of the component.

9. The component mounting system according to claim 3, wherein the display controller is configured to control the display such that the plurality of error data sets that constitute the data set group is displayed in order of the occurrence count of the error.

10. The component mounting system according to claim 3, wherein
the storage is configured, when there is a waste component indicating the component discarded together with the component loading board due to an inspection error in an inspection device, to accumulate and store the management data to which inspection error information for identifying the waste component is added,
the data generator is configured, when the inspection error information is added to the management data, to generate inspection error loss amount data about the amount of loss of the waste component in association with the inspection error information, and
when a command to display data about the waste component is input via the operating unit, the display controller is configured to control the display such that the inspection error loss amount data is displayed.

11. The component mounting system according to claim 3, wherein
the data generator is configured to generate the error loss amount data in a state divided into an error type indicating a type of the error, and
when a command to display data for each error type is input via the operating unit, the display controller is configured to control the display such that the error loss amount data is displayed in a state divided into the error type.

12. The component mounting system according to claim 3, wherein
the component mounting line includes a plurality of mounting lines, and
when a command to display the data set group for each of the plurality of mounting lines is input via the operating unit, the display controller is configured to control the display such that the data set groups corresponding to the plurality of mounting lines are simultaneously displayed in display regions individually set for the plurality of mounting lines.

13. The component mounting system according to claim 2, wherein when a plurality of pieces of production factor information is set for the production factors, the display controller is configured to control the display such that a data set group of a plurality of the error data sets associated with the plurality of pieces of production factor information is displayed.

14. The component mounting system according to claim 13, wherein when a command to select a plurality of the production factors from the production factors is input via the operating unit as the factor selection command, the display controller is configured to control the display such that a plurality of the data set groups corresponding to the plurality of production factors is displayed simultaneously in a state divided into the plurality of production factors.

15. The component mounting system according to claim 14, wherein with the data set groups respectively corresponding to the plurality of production factors simultaneously displayed in the display, when a command to select one piece of production factor information from among the plurality of pieces of production factor information set for the plurality of production factors is input via the operating unit, the display controller is configured to control the display such that only the error data set related to the one piece of production factor information is displayed.
